(19) United States
(12) Patent Application Publication
(10) Pub. No.: US 2026/0113983 A1
(43) Pub. Date: Apr. 23, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ta-Chun LIN, Hsinchu City (TW); Jhon-Jhy LIAW, Zhudong Township (TW)

(21) Appl. No.: 18/919,691

(22) Filed: Oct. 18, 2024

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 84/013; H10D 84/0149; H10D 84/0151; H10D 84/038; H10D 84/83

(57) ABSTRACT

Semiconductor structures and methods for manufacturing the same are provided. The semiconductor structure includes an isolation structure formed over a substrate, and a mask layer formed over the isolation structure. The semiconductor structure includes nanostructures formed over the substrate along a first direction, and a dielectric layer below the nanostructures along the first direction. The semiconductor structure also includes a gate structure formed over the nanostructures along a second direction. The semiconductor structure includes a gate spacer layer formed adjacent to the gate structure along the second direction, and the mask layer is directly below the gate spacer layer.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIGS. 2A to 2E illustrate top views of intermediate stages of manufacturing the semiconductor structure, in accordance with some embodiments.

FIGS. 3A-1 to 3O-1 illustrate cross-sectional representations of various stages of manufacturing the semiconductor structure shown along line Y1-Y1′ in FIGS. 1D, 1E, 2D and 2E, in accordance with some embodiments.

FIGS. 3A-2 to 3O-2 illustrate cross-sectional representations of various stages of manufacturing the semiconductor structure shown along line Y2-Y2′ in FIGS. 1D, 1E, 2D and 2E, in accordance with some embodiments.

FIGS. 3A-3 to 3O-3 illustrate cross-sectional representations of various stages of manufacturing the semiconductor structure shown along line X1-X1′ in FIGS. 1D, 1E, 2D and 2E, in accordance with some embodiments.

FIGS. 3A-4 to 3O-4 illustrate cross-sectional representations of various stages of manufacturing the semiconductor structure shown along line X2-X2′ in FIGS. 1D, 1E, 2D and 2E, in accordance with some embodiments.

FIG. 4 illustrates a top view of the semiconductor structure, in accordance with some embodiments.

FIG. 5 illustrates a top view of a semiconductor structure, in accordance with some embodiments.

FIG. 6A-1 illustrates the cross-sectional representation shown along line Y1-Y1′ in FIG. 5, in accordance with some embodiments.

FIG. 6A-2 illustrates the cross-sectional representation shown along line Y2-Y2′ in FIG. 5, in accordance with some embodiments.

FIG. 6A-3 illustrates the cross-sectional representation shown along line X1-X1′ in FIG. 5, in accordance with some embodiments.

FIG. 6A-4 illustrates the cross-sectional representation shown along line X2-X2′ in FIG. 5, in accordance with some embodiments.

FIG. 7 illustrates a perspective view of a semiconductor structure, in accordance with some embodiments.

FIG. 8A-1 illustrates the cross-sectional representation shown along line Y1-Y1′ in FIG. 7, in accordance with some embodiments.

FIG. 8A-2 illustrates the cross-sectional representation shown along line Y2-Y2′ in FIG. 7, in accordance with some embodiments.

FIG. 8A-3 illustrates the cross-sectional representation shown along line X1-X1′ in FIG. 7, in accordance with some embodiments.

FIG. 8A-4 illustrates the cross-sectional representation shown along line X2-X2′ in FIG. 7, in accordance with some embodiments.

FIG. 9 illustrates a perspective view of a semiconductor structure, in accordance with some embodiments.

FIG. 10A-1 illustrates the cross-sectional representation shown along line Y1-Y1′ in FIG. 9, in accordance with some embodiments.

FIG. 10A-2 illustrates the cross-sectional representation shown along line Y2-Y2′ in FIG. 9, in accordance with some embodiments.

FIG. 10A-3 illustrates the cross-sectional representation shown along line X1-X1′ in FIG. 9, in accordance with some embodiments.

FIG. 10A-4 illustrates the cross-sectional representation shown along line X2-X2′ in FIG. 9, in accordance with some embodiments.

FIG. 11 illustrates a perspective view of a semiconductor structure, in accordance with some embodiments.

FIG. 12A-1 illustrates the cross-sectional representation shown along line Y1-Y1′ in FIG. 11, in accordance with some embodiments.

FIG. 12A-2 illustrates the cross-sectional representation shown along line Y2-Y2′ in FIG. 11, in accordance with some embodiments.

FIG. 12A-3 illustrates the cross-sectional representation shown along line X1-X1′ in FIG. 11, in accordance with some embodiments.

FIG. 12A-4 illustrates the cross-sectional representation shown along line X2-X2′ in FIG. 11, in accordance with some embodiments.

FIG. 13 illustrates a perspective view of a semiconductor structure, in accordance with some embodiments.

FIG. 14A-1 illustrates the cross-sectional representation shown along line Y1-Y1′ in FIG. 13, in accordance with some embodiments.

FIG. 14A-2 illustrates the cross-sectional representation shown along line Y2-Y2′ in FIG. 13, in accordance with some embodiments.

FIG. 14A-3 illustrates the cross-sectional representation shown along line X1-X1′ in FIG. 13, in accordance with some embodiments.

FIG. 14A-4 illustrates the cross-sectional representation shown along line X2-X2′ in FIG. 13, in accordance with some embodiments.

FIG. 15 illustrates a perspective view of a semiconductor structure, in accordance with some embodiments.

FIG. 16A-1 illustrates the cross-sectional representation shown along line Y1-Y1′ in FIG. 15, in accordance with some embodiments.

FIG. 16A-2 illustrates the cross-sectional representation shown along line Y2-Y2′ in FIG. 15, in accordance with some embodiments.

FIG. 16A-3 illustrates the cross-sectional representation shown along line X1-X1′ in FIG. 15, in accordance with some embodiments.

FIG. 16A-4 illustrates the cross-sectional representation shown along line X2-X2′ in FIG. 15, in accordance with some embodiments.

FIG. 17 illustrates a perspective view of a semiconductor structure, in accordance with some embodiments.

FIG. 18A-1 illustrates the cross-sectional representation shown along line Y1-Y1′ in FIG. 17, in accordance with some embodiments.

FIG. 18A-2 illustrates the cross-sectional representation shown along line Y2-Y2′ in FIG. 17, in accordance with some embodiments.

FIG. 18A-3 illustrates the cross-sectional representation shown along line X1-X1′ in FIG. 17, in accordance with some embodiments.

FIG. 18A-4 illustrates the cross-sectional representation shown along line X2-X2′ in FIG. 17, in accordance with some embodiments.

FIG. 19 illustrates a perspective view of a semiconductor structure, in accordance with some embodiments.

FIG. 20A-1 illustrates the cross-sectional representation shown along line Y1-Y1′ in FIG. 19, in accordance with some embodiments.

FIG. 20A-2 illustrates the cross-sectional representation shown along line Y2-Y2′ in FIG. 19, in accordance with some embodiments.

FIG. 20A-3 illustrates the cross-sectional representation shown along line X1-X1′ in FIG. 19, in accordance with some embodiments.

FIG. 20A-4 illustrates the cross-sectional representation shown along line X2-X2′ in FIG. 19, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. A number of nanostructures are formed over a substrate, and a dielectric layer is formed below the nanostructures to protect the nanostructures. An isolation structure formed over the substrate, and a mask layer is formed on the isolation structure to protect the isolation structure. A gate structure is formed on the nanostructures, and gate spacer layers are formed on opposite sidewall surfaces of the gate structure. An S/D structure is formed adjacent to the gate structure. A bottom isolation layer is formed below the S/D structure to reduce the leakage. A back-side contact structure is formed below the S/D structure. When a trench of the back-side contact structure is formed, the dielectric layer directly below the nanostructures and the mask layer directly below the gate structure are used as etch stop layer to protect the nanostructures and gate structure. Therefore, the risk of short problem can be reduced. In addition, the mask layer is used to protect the isolation structure from being etched or damaged during the nanostructures formation process. Therefore, the unwanted capacitance can be reduced. The mask layer directly on the isolation structure, the dielectric layer directly below the nanostructures, and the bottom isolation layer directly below the S/D structure have different functions to improve the performance of semiconductor structure. The source/drain (S/D) structure or region(s) may refer to a source or a drain, individually or collectively dependent upon the context.

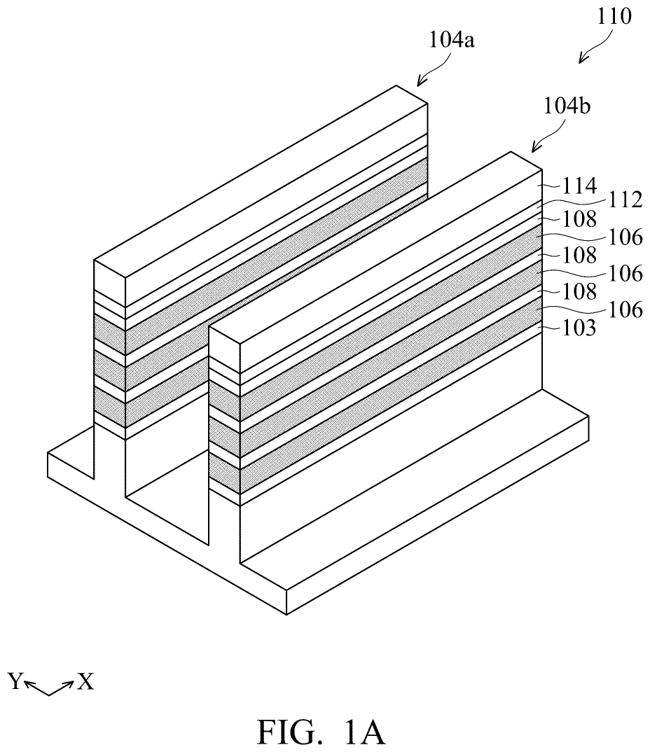

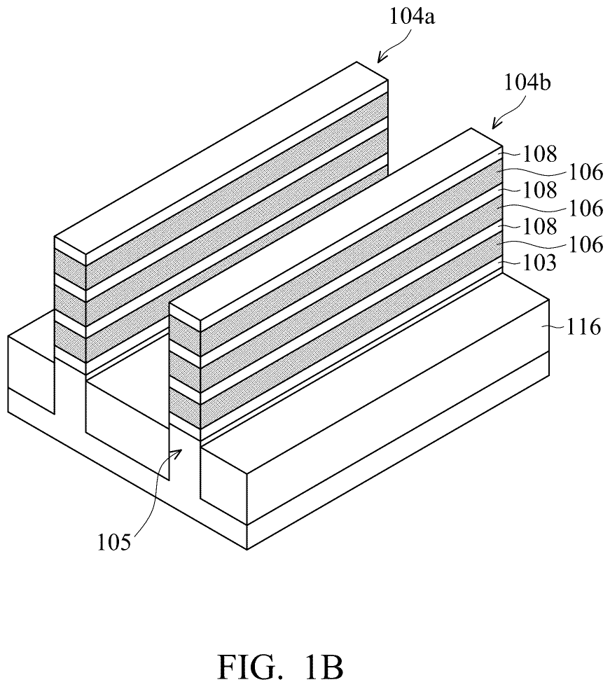

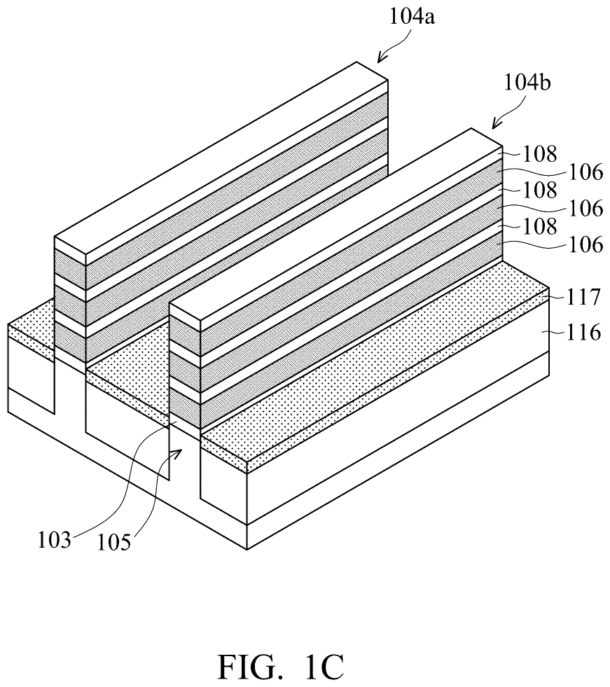

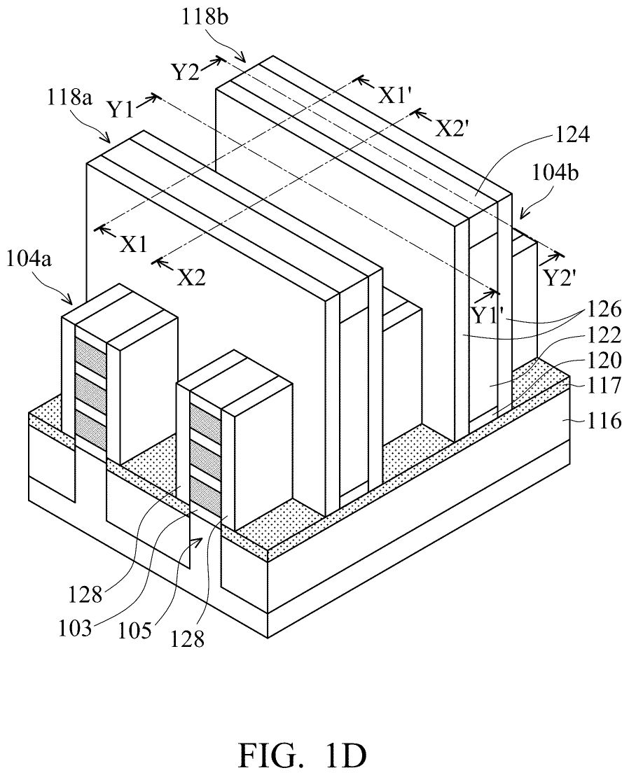

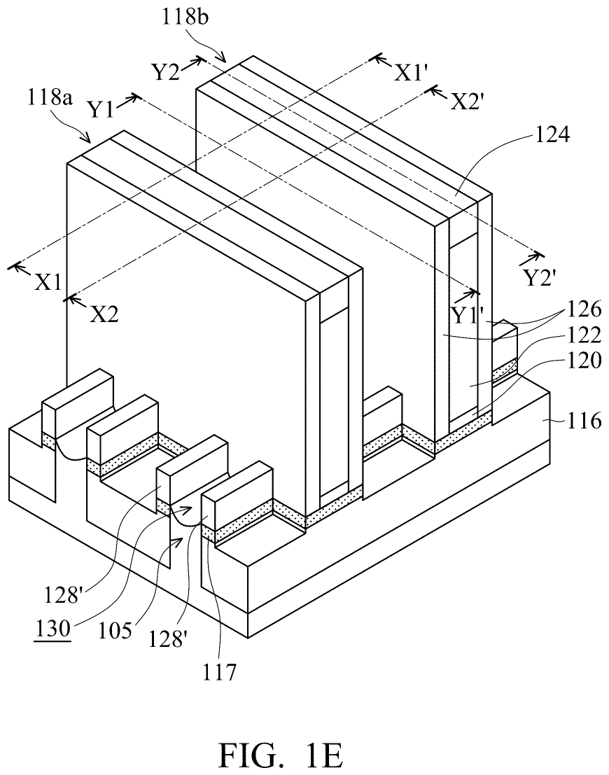

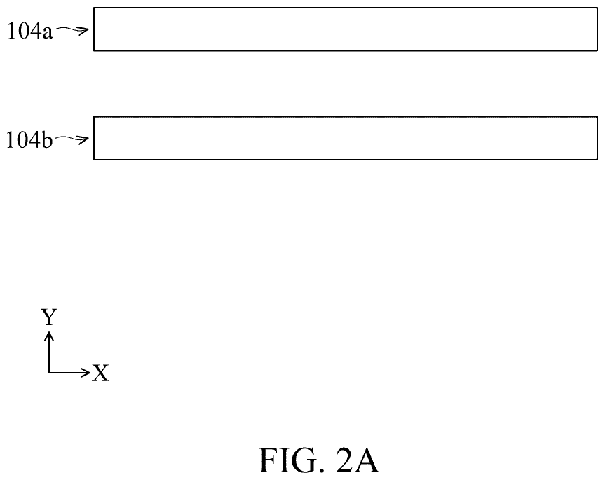

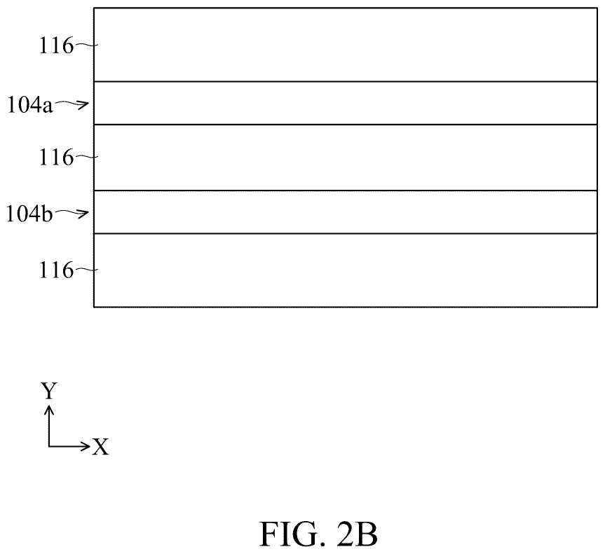

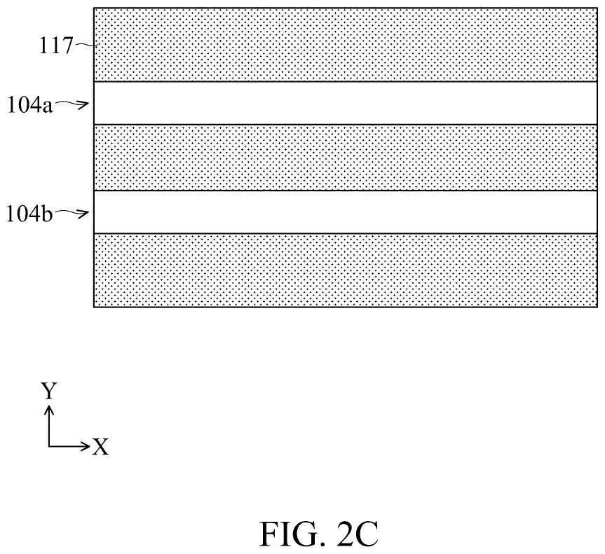

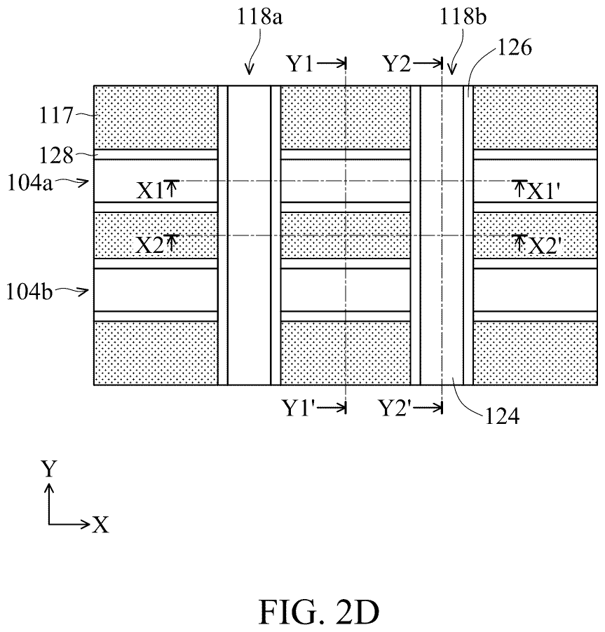

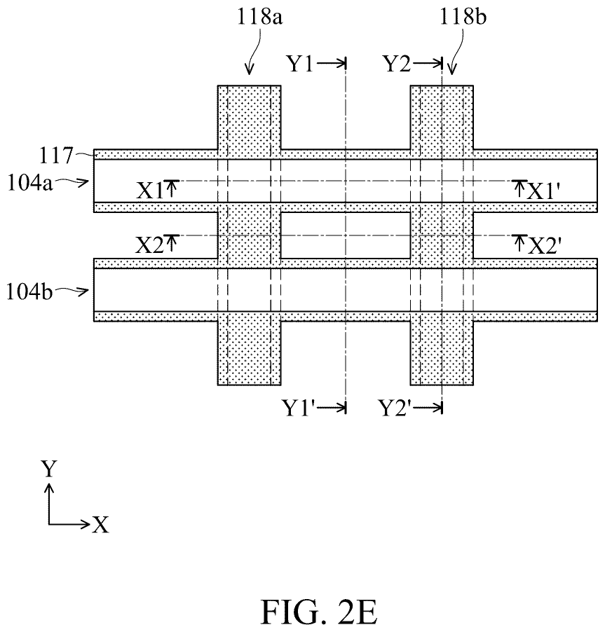

FIGS. 1A to 1E illustrate perspective views of intermediate stages of manufacturing a semiconductor structure 100a, in accordance with some embodiments. FIGS. 2A to 2E illustrate top views of intermediate stages of manufacturing the semiconductor structure 100a, in accordance with some embodiments.

As shown in FIGS. 1A and 2A, a sacrificial layer 103 and a stack are formed over a substrate 102. The stack includes first semiconductor material layers 106 and second semiconductor material layers 108 alternatively stacked. The sacrificial layer 103 will be replaced with dielectric material to use as an etch stop layer.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the sacrificial layer 103 is made of SiGe. In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers. In some embodiments, when the sacrificial layer 103 and the first semiconductor material layers 106 are made of SiGe, the Ge concentration of the sacrificial layer 103 is greater than the Ge concentration of the first semiconductor material layers 106.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

Afterwards, after the sacrificial layer 103, the first semiconductor material layers 106 and the second semiconductor material layers 108 are formed as a semiconductor material stack over the substrate 102, the semiconductor material stack is patterned to form a first fin structure 104a and a second fin structure 104b, in accordance with some embodiments. In some embodiments, each of the first fin structure 104a and a second fin structure 104b includes a base fin structure 105 and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-temperature chemical vapor deposition (LPCVD) or plasma-enhanced CVD (PECVD).

Next, as shown in FIGS. 1B and 2B, after the first fin structure 104a and the second fin structure 104b is formed, an isolation structure 116 is formed around first fin structure 104a and the second fin structure 104b, and the mask structure 110 is removed, in accordance with some embodiments. The isolation structure 116 is configured to electrically isolate active regions (e.g. the first fin structure 104a and the second fin structure 104b) of the semiconductor structure 100a and is also referred to as shallow trench isolation (STI) feature in accordance with some embodiments.

The isolation structure 116 may be formed by depositing an insulating layer over the substrate 102 and recessing the insulating layer so that the first fin structure 104a and the second fin structure 104b are protruded from the isolation structure 116.

In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

Afterwards, as shown in FIGS. 1C and 2C, a mask layer 117 is formed on the isolation structure 116, in accordance with some embodiments. The mask layer 117 is used to as an etch stop layer when forming a trench form back-side of the substrate 102. In addition, the mask layer 117 is used as a protection layer to protect the isolation structure 116.

In some embodiments, the mask layer 107 is made of silicon nitride (SiN), silicon oxide (SiOx), silicon oxynitride (SiON), silicon carbon nitride (SiCN), silicon oxide carbonitride (SiOCN), Silicon oxycarbide (SiCO), silicon carbide (SIC), high-k dielectric material (HfO or AlOx), or another applicable material. In some embodiments, the mask layer 117 is formed by chemical vapor deposition (CVD), ALD, other application methods, or a combination thereof.

Next, as shown in FIGS. 1D and 2D, after the mask layer 117 is formed, first dummy gate structures 118a and second dummy gate structures 118b are formed across the first fin structure 104a and the second fin structure 104b and extend over the isolation structure 116, in accordance with some embodiments. The first dummy gate structures 118a and the second dummy gate structures 118b may be used to define the source/drain (S/D) regions and the channel regions of the resulting semiconductor structure 100a.

In some embodiments, each of the first dummy gate structures 118a and each of the second dummy gate structures 118b includes dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

In some embodiments, hard mask layers 124 are formed over the dummy gate structures 118. In some embodiments, the hard mask layers 124 include multiple layers, such as an oxide layer and a nitride layer. In some embodiments, the oxide layer is silicon oxide, and the nitride layer is silicon nitride.

The formation of the dummy gate structures 118 may include conformally forming a dielectric material as the dummy gate dielectric layers 120. Afterwards, a conductive material may be formed over the dielectric material as the dummy gate electrode layers 122, and the hard mask layer 124 may be formed over the conductive material. Next, the dielectric material and the conductive material may be patterned through the hard mask layer 124 to form the dummy gate structures 118.

Next, after the dummy gate structures 118 are formed, gate spacer layers 126 are formed along and covering opposite sidewalls of the dummy gate structure 118 and fin spacer layers 128 are formed along and covering opposite sidewalls of the source/drain regions of the fin structure 104, in accordance with some embodiments.

The gate spacer layers 126 may be configured to separate source/drain (S/D) structures from the first dummy gate structure 118a, the second dummy gate structures 118b and support the first dummy gate structure 118a, the second dummy gate structures 118b, and the fin space layers 128 may be configured to constrain a lateral growth of subsequently formed source/drain structure and support the first fin structure 104a and the second fin structure 104b.

In some embodiments, the gate spacer layers 126 and the fin spacer layers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacer layers 126 and the fin spacer layers 128 may include conformally depositing a dielectric material covering the first dummy gate structure 118a, the second dummy gate structure 118b, the first fin structure 104a, the second fin structure 104b and the isolation structure 116 over the substrate 102, and performing an anisotropic etching process, such as dry plasma etching, to remove the dielectric layer covering the top surfaces of the first dummy gate structure 118a, the second dummy gate structure 118b, the first fin structure 104a, the second fin structure 104b, and portions of the isolation structure 116.

Next, as shown in FIGS. 1E and 2E, the source/drain (S/D) regions of the first fin structure 104a and the second fin structure 104b are recessed to form source/drain (S/D) recesses 130, and a portion of the mask layer 117 is removed, in accordance with some embodiments. As a result, the remaining mask layer 117 is formed directly below the dummy gate structure 180, the gate spacer layer 126 and the fin spacer layer 128.

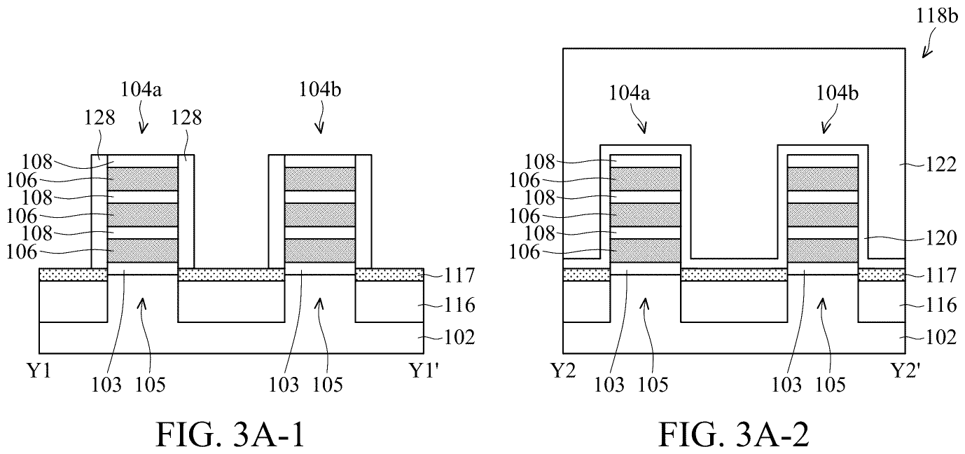

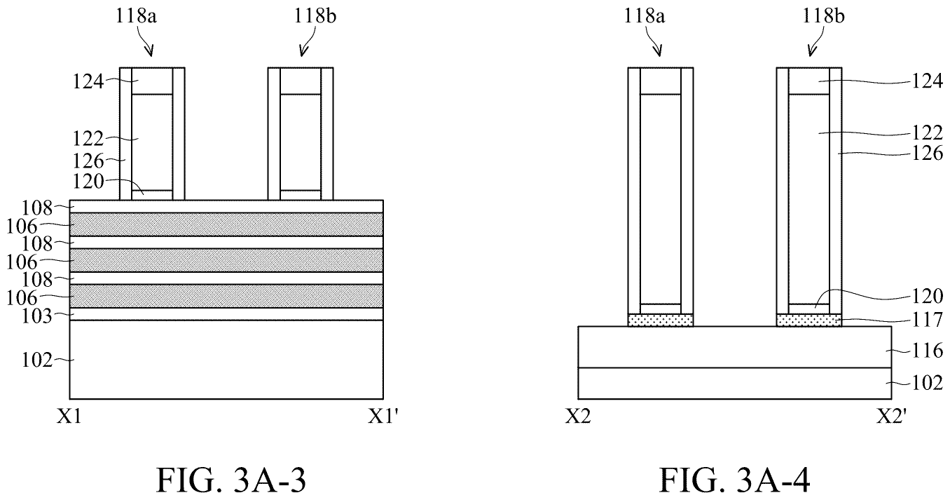

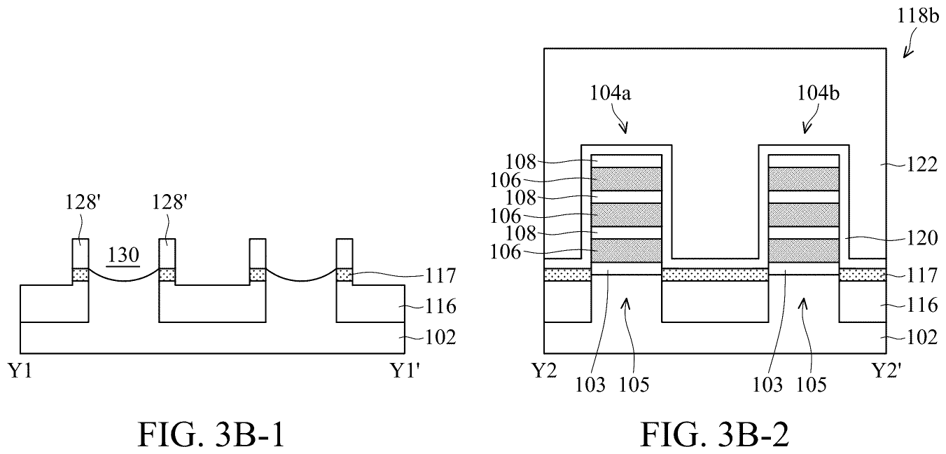

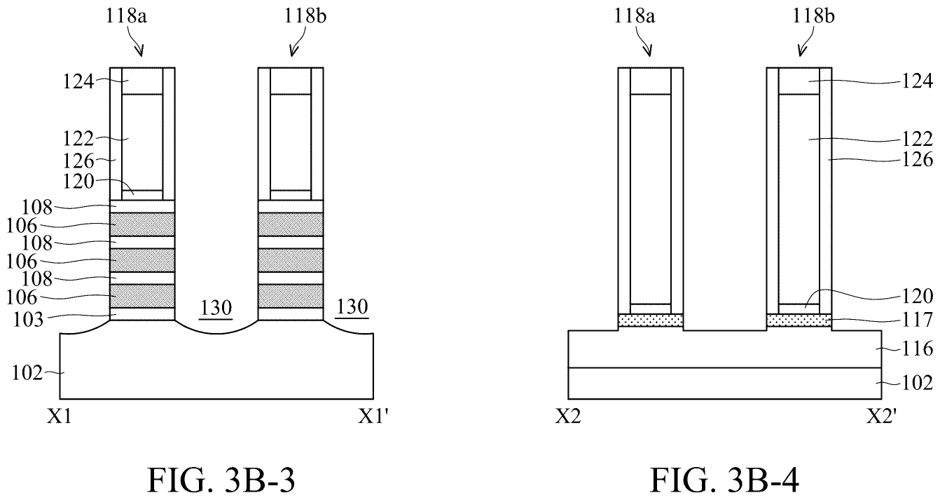

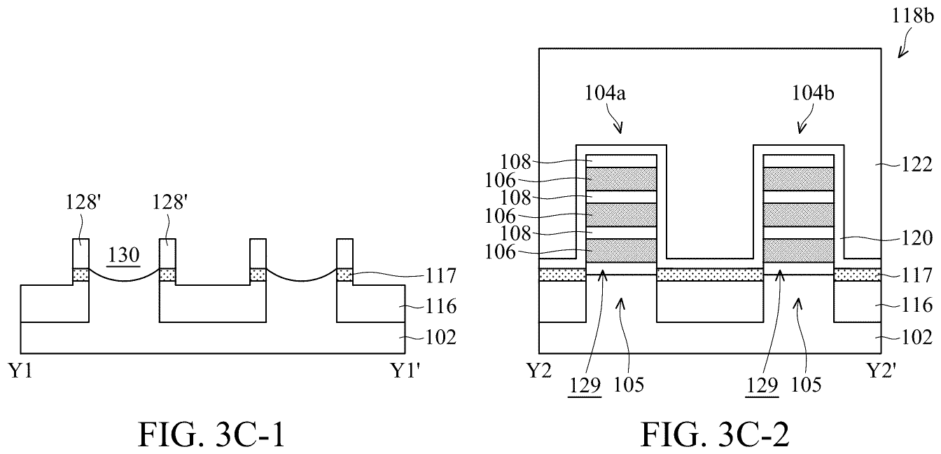

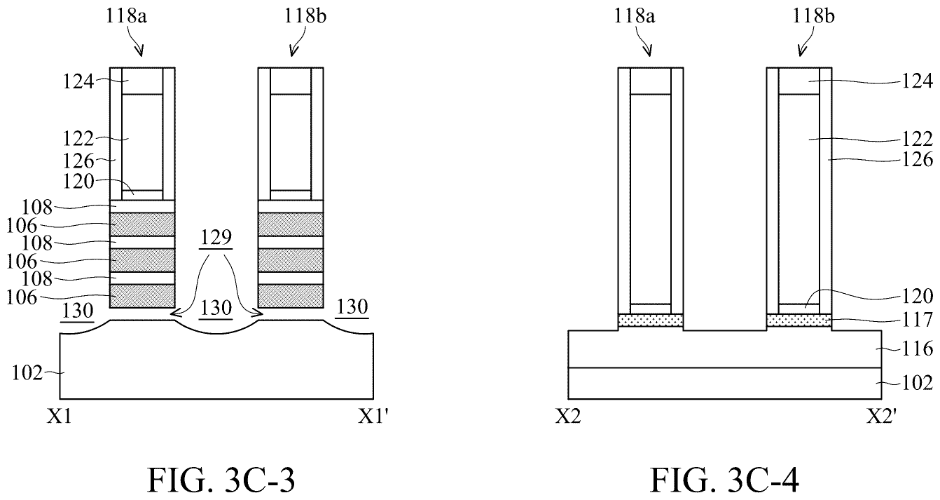

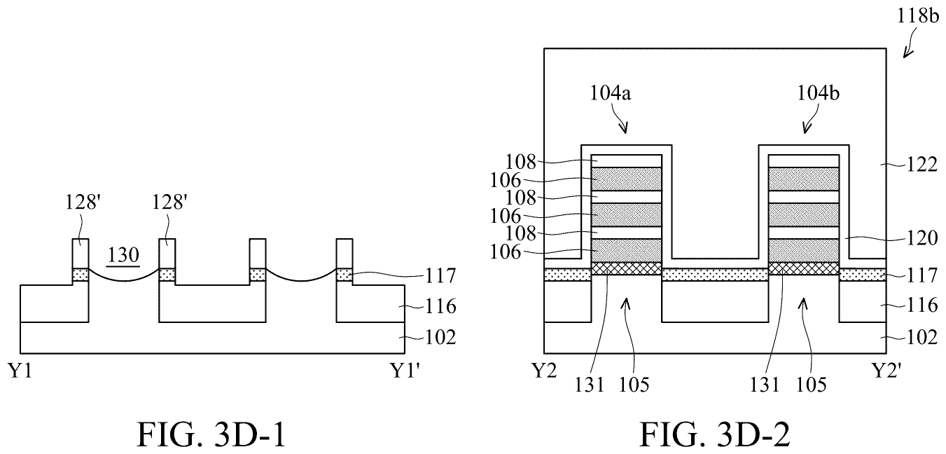

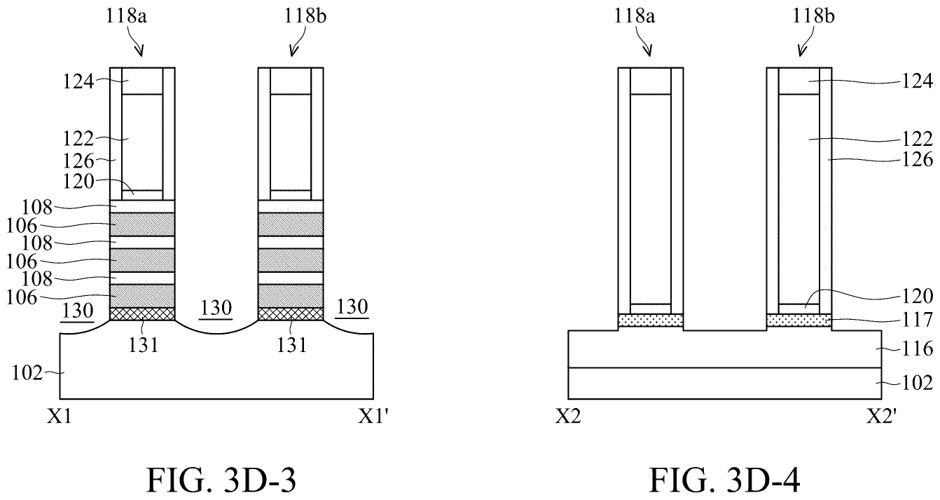

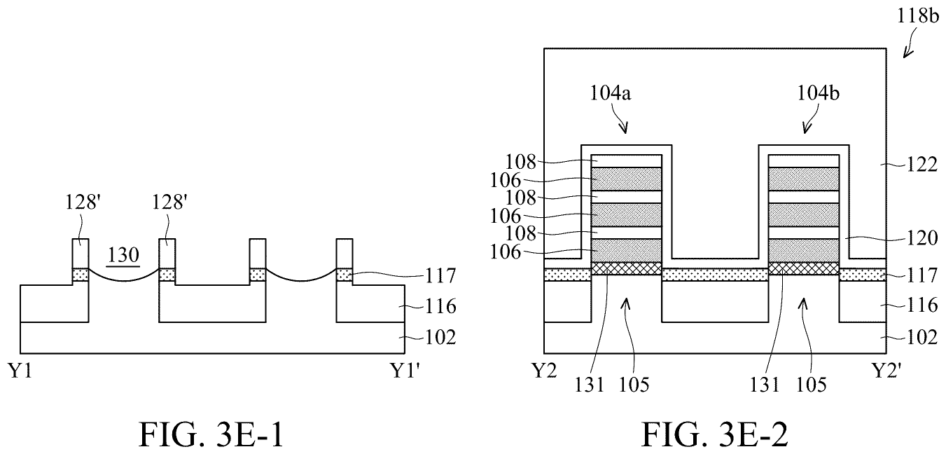

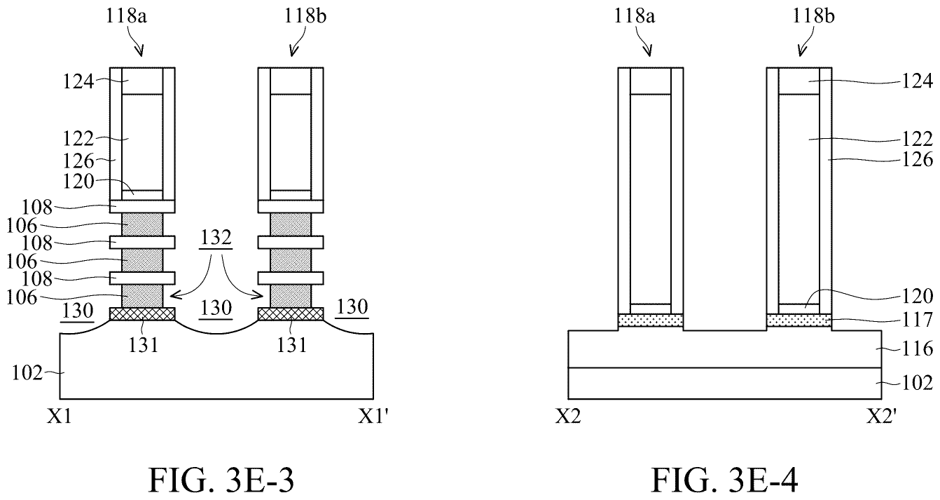

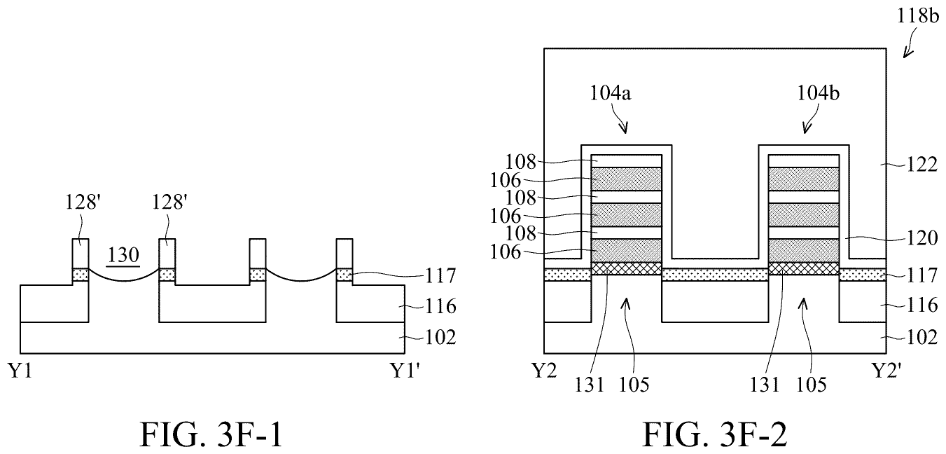

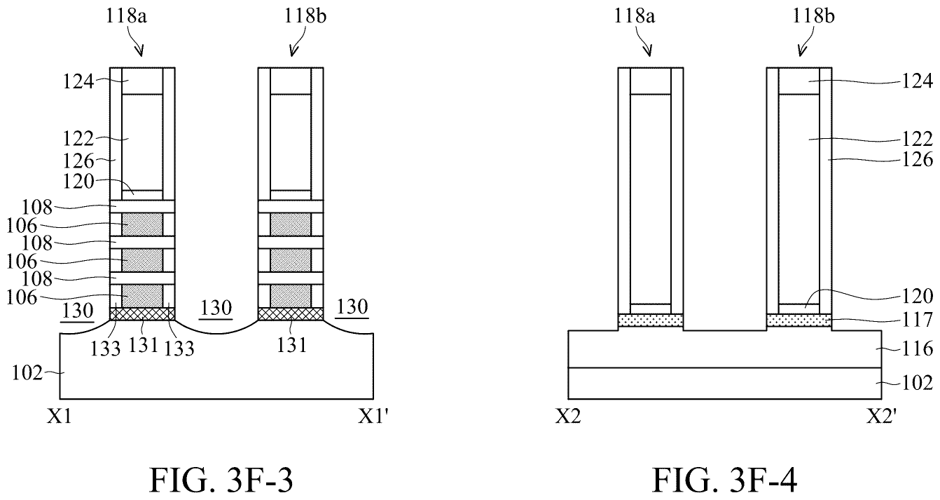

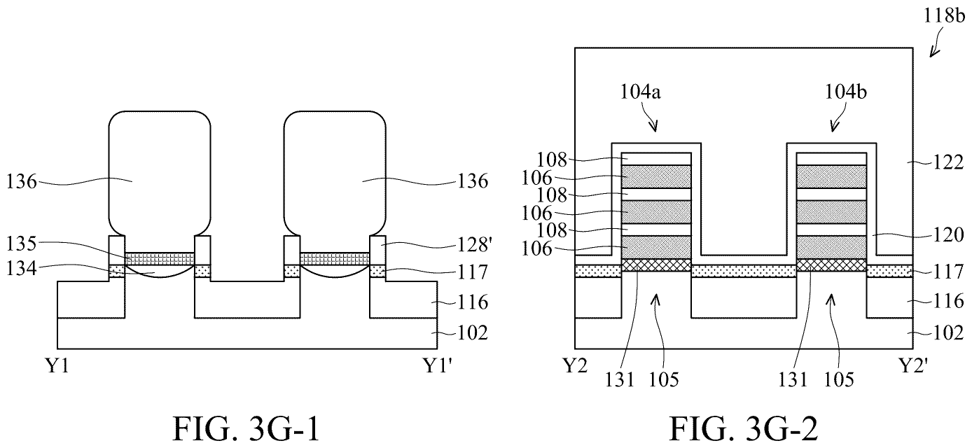

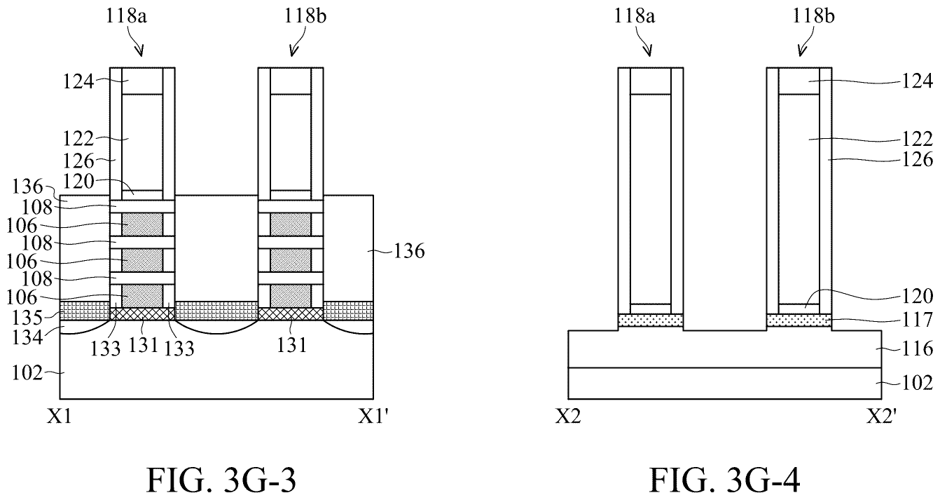

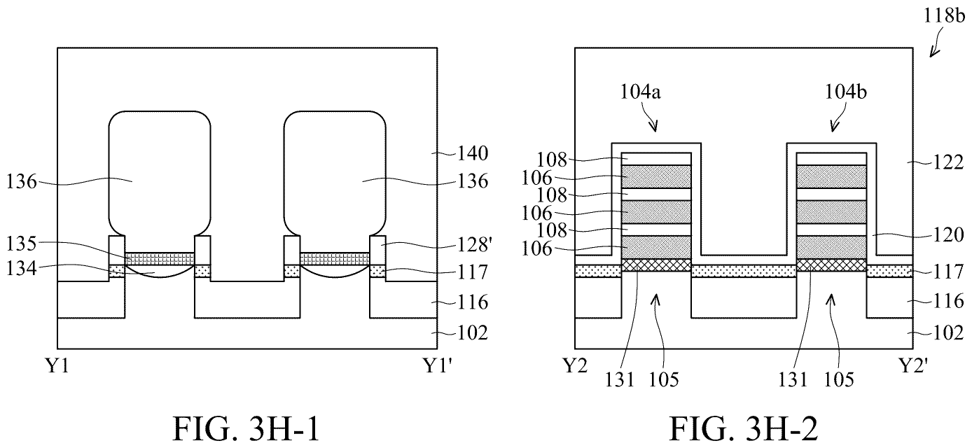

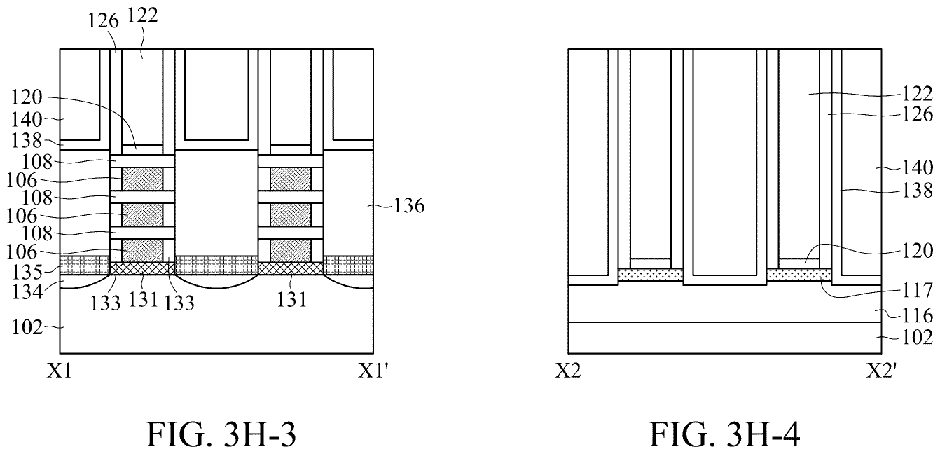

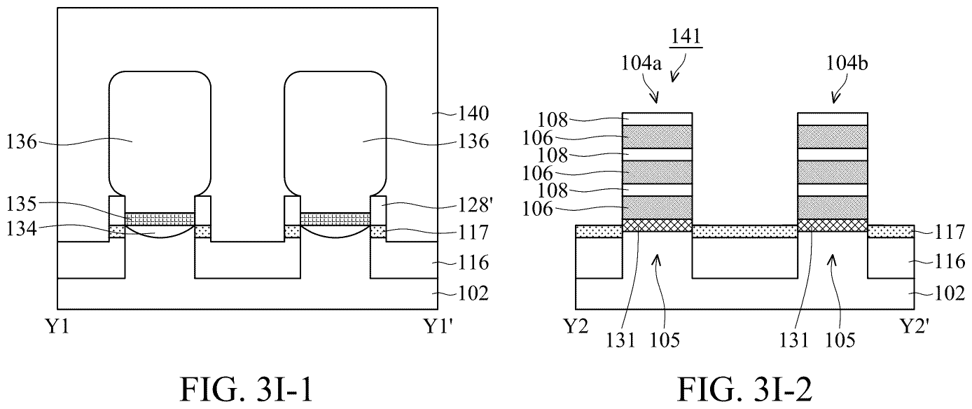

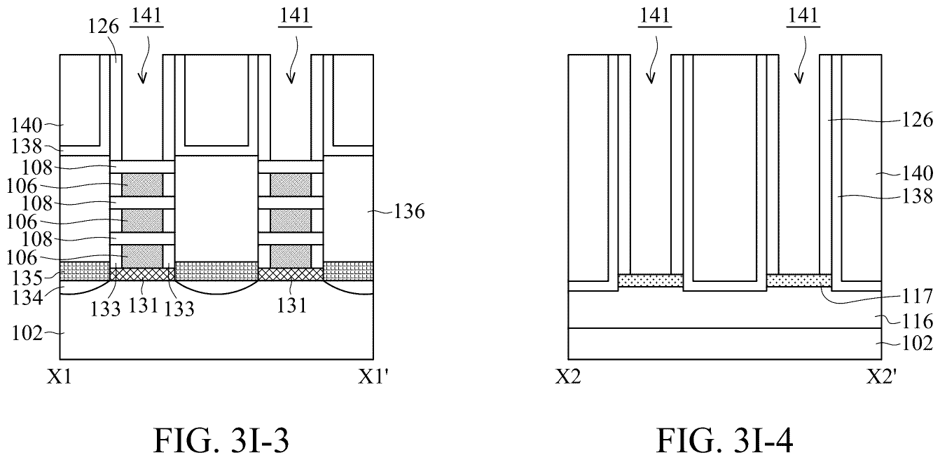

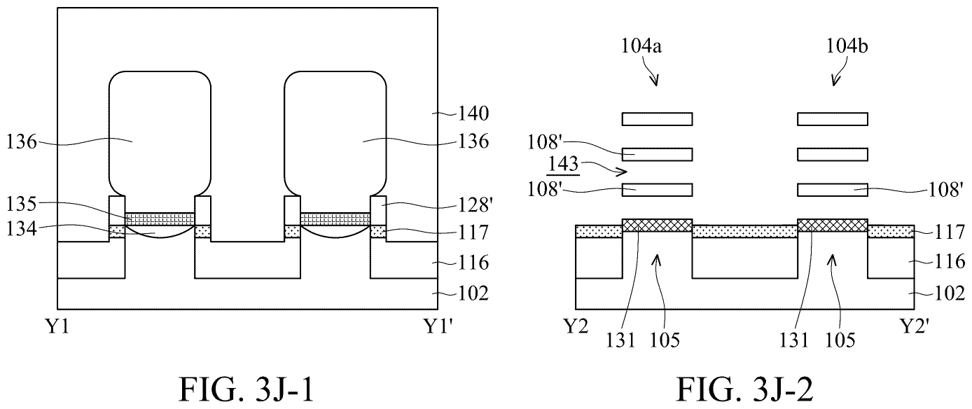

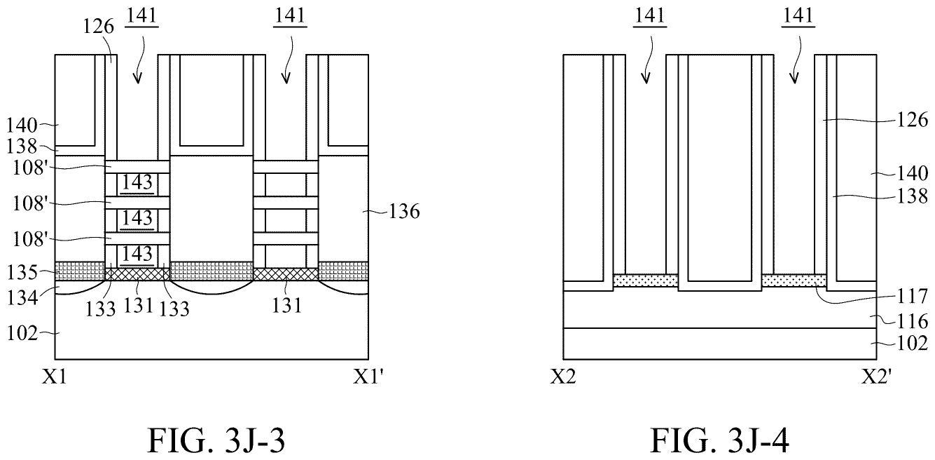

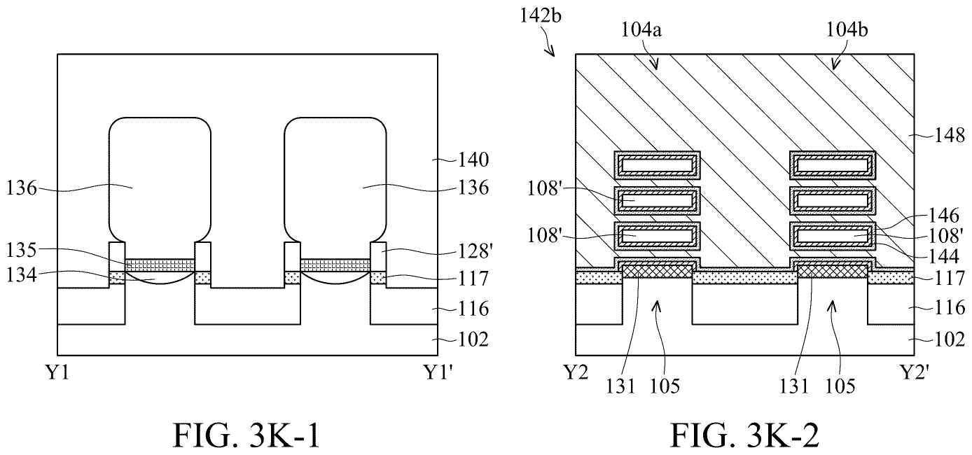

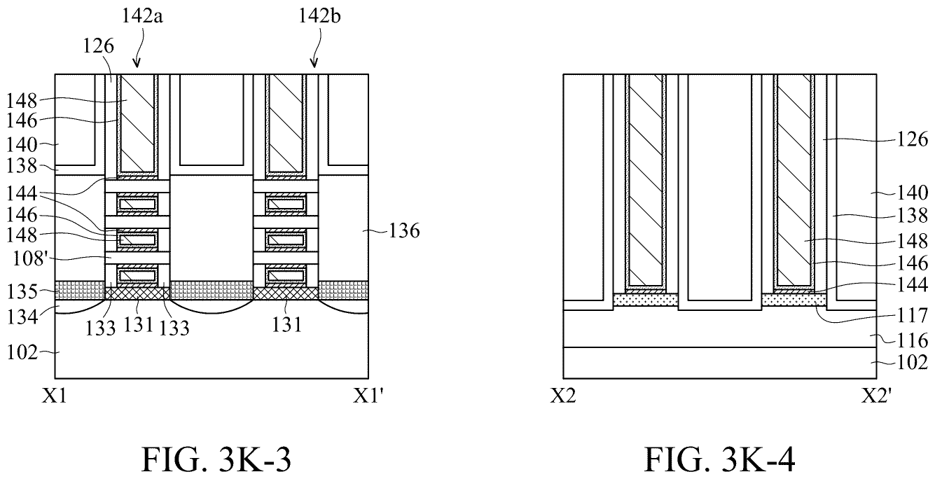

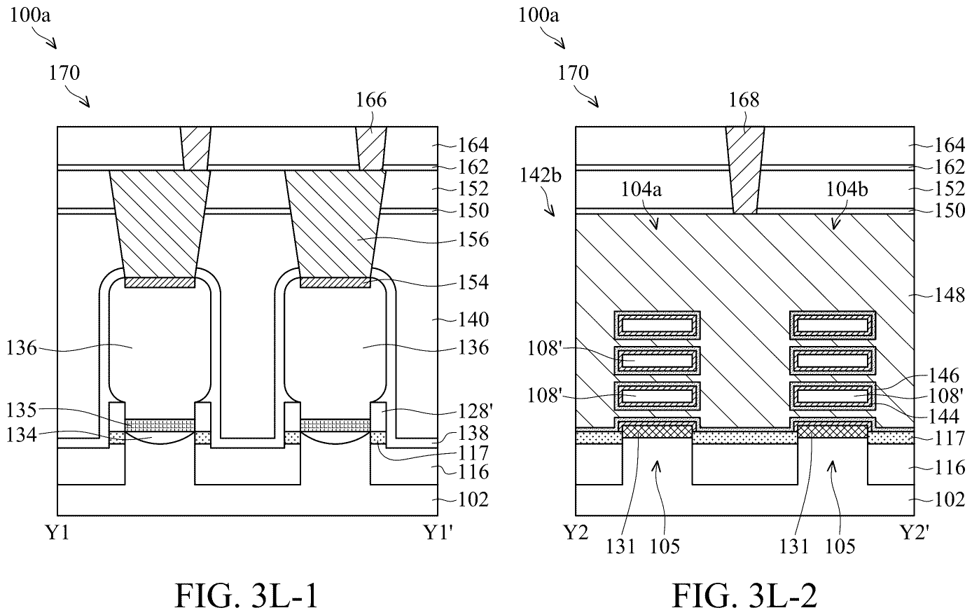

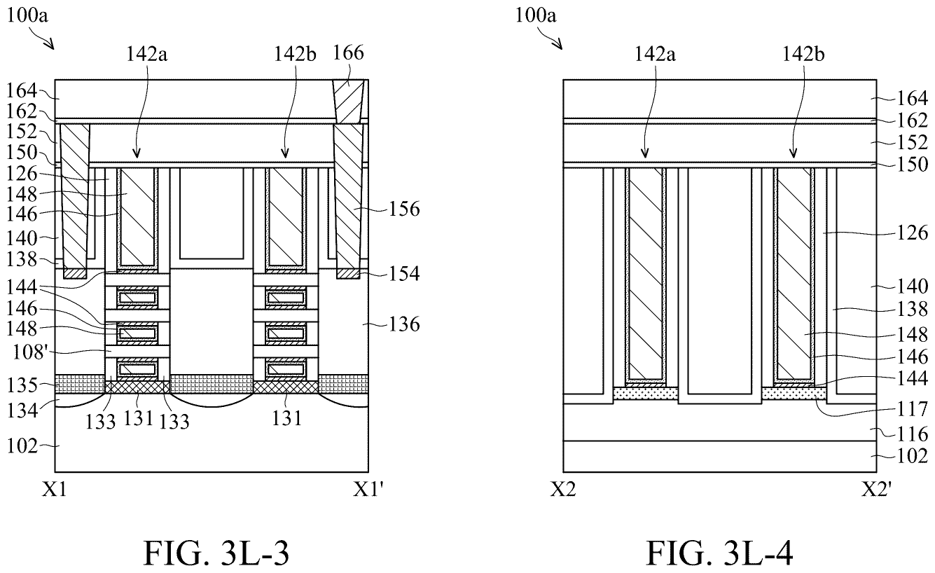

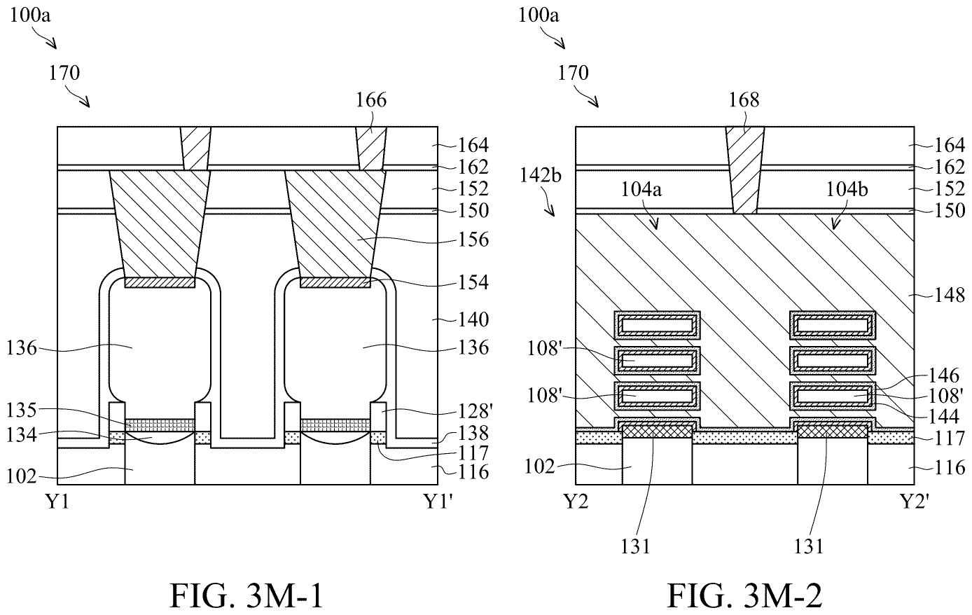

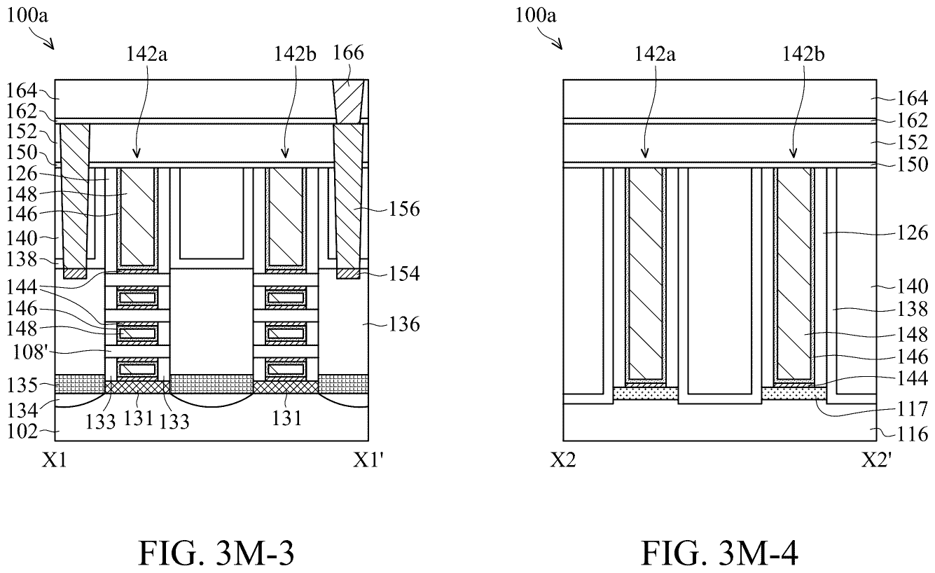

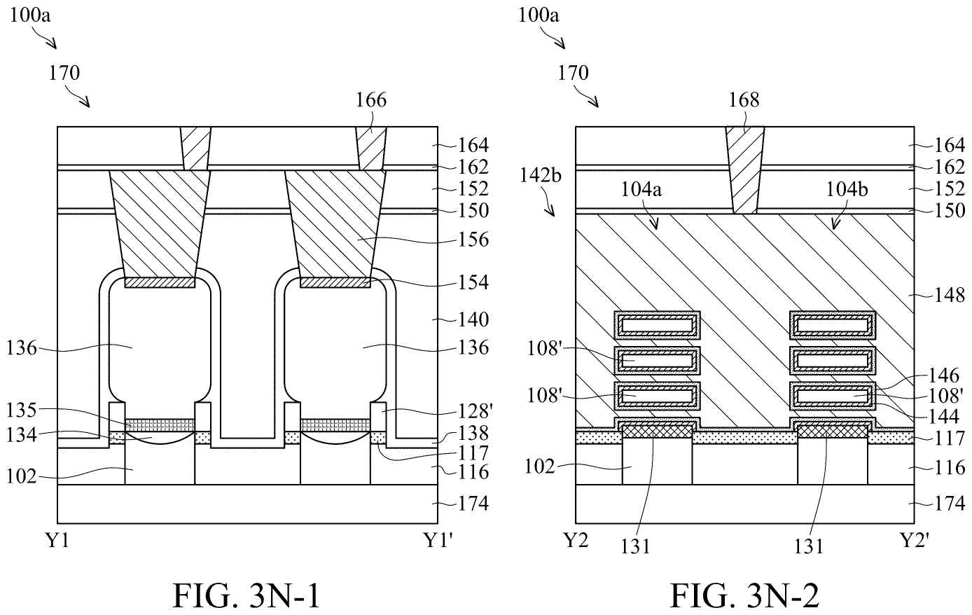

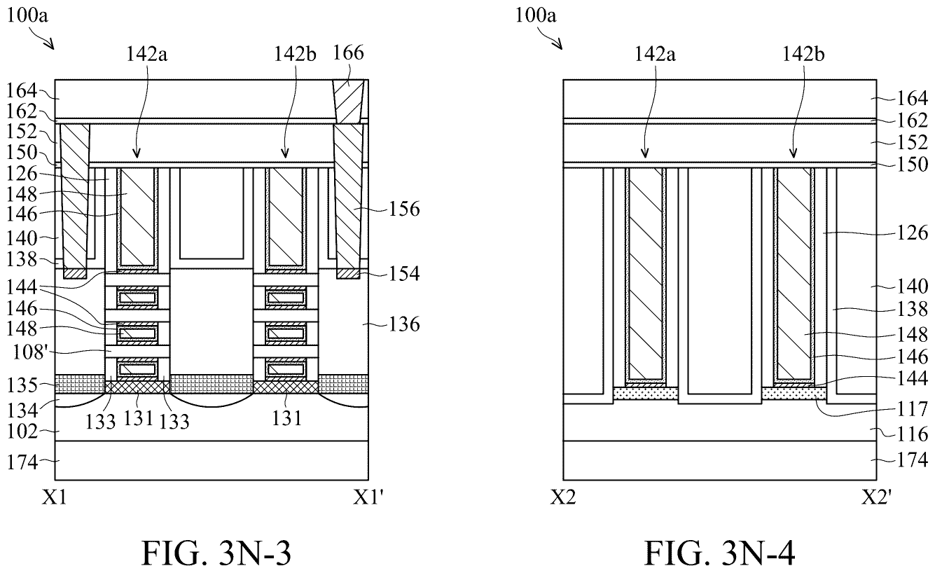

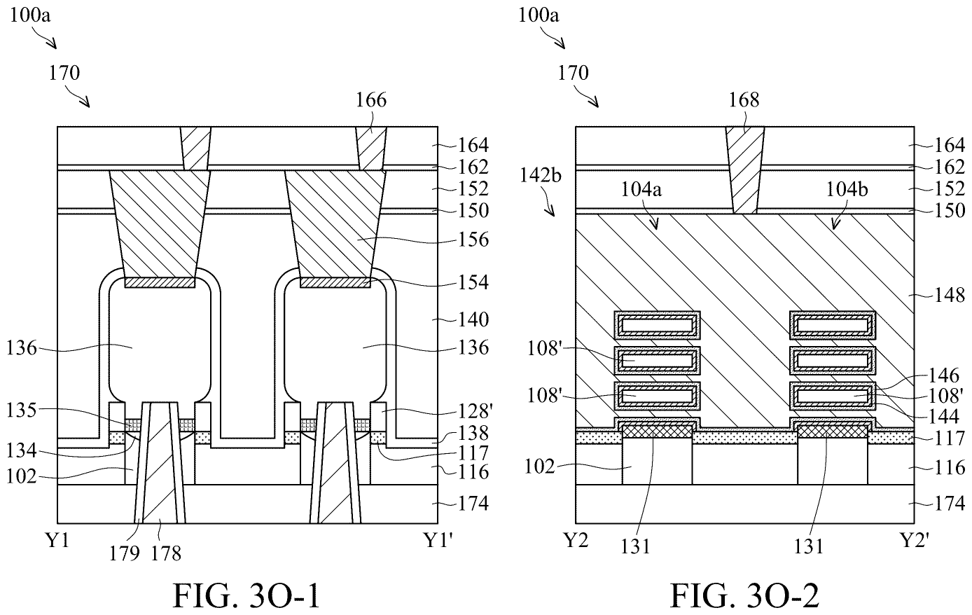

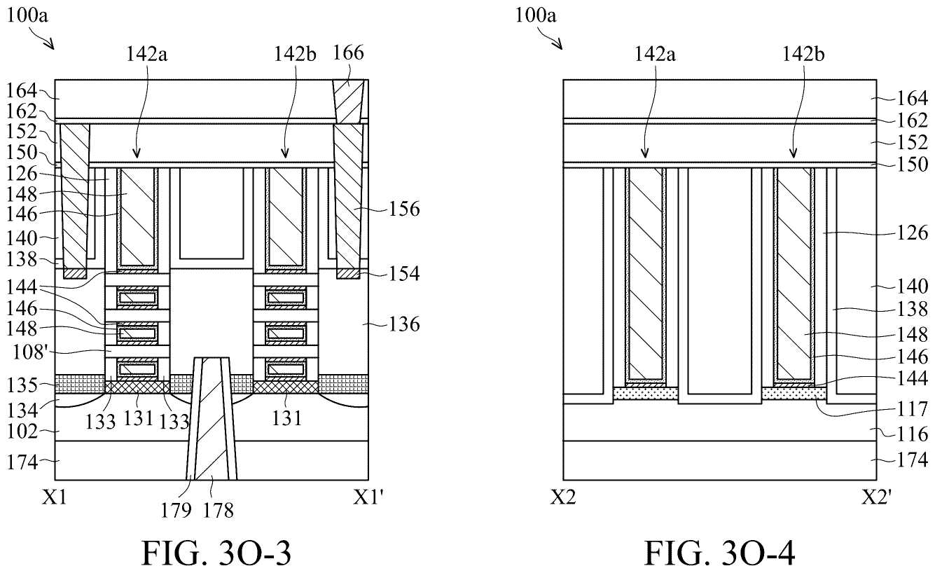

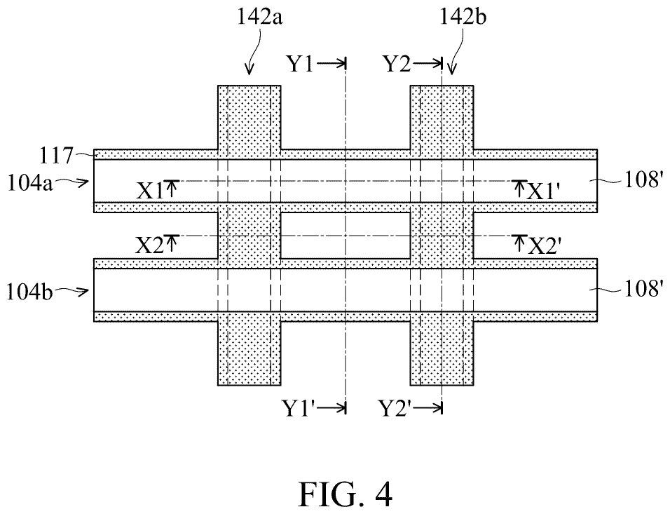

FIGS. 3A-1 to 3O-1 illustrate cross-sectional representations of various stages of manufacturing the semiconductor structure 100a shown along line Y1-Y1′ in FIGS. 1D, 1E, 2D and 2E, in accordance with some embodiments. FIGS. 3A-2 to 3O-2 illustrate cross-sectional representations of various stages of manufacturing the semiconductor structure 100a shown along line Y2-Y2′ in FIGS. 1D, 1E, 2D and 2E, in accordance with some embodiments. FIGS. 3A-3 to 3O-3 illustrate cross-sectional representations of various stages of manufacturing the semiconductor structure 100a shown along line X1-X1′ in FIGS. 1D, 1E, 2D and 2E, in accordance with some embodiments. FIGS. 3A-4 to 3O-4 illustrate cross-sectional representations of various stages of manufacturing the semiconductor structure 100a shown along line X2-X2′ in FIGS. 1D, 1E, 2D and 2E, in accordance with some embodiments.

More specifically, FIG. 3A-1 illustrates the cross-sectional representation shown along line Y1-Y1′ in FIGS. 1D and 2D. FIG. 3A-2 illustrates the cross-sectional representation shown along line Y2-Y2′ in FIGS. 1D and 2D, in accordance with some embodiments. FIG. 3A-3 illustrates the cross-sectional representation shown along line X1-X1′ in FIGS. 1D and 2D. FIG. 3A-4 illustrates the cross-sectional representation shown along line X2-X2′ in FIGS. 1D and 2D.

As shown in FIG. 3A-1, the first fin structure 104a and the second fin structure 104b are formed over the substrate 102 in the S/D region, and the sacrificial layer 103 is directly below the stack layer including the first semiconductor material layers 106 and second semiconductor material layers 108. The mask layer 117 is directly below the fin spacer layer 128. The mask layer 117 is between the fin spacer layer 128 and isolation structure 116.

As shown in FIG. 3A-2, the first fin structure 104a and the second fin structure 104b are formed in over the substrate 102 in the gate region, and the sacrificial layer 103 is directly below the stack layer including the first semiconductor material layers 106 and second semiconductor material layers 108. The second dummy gate structure 118b is formed on the first fin structure 104a, the second fin structure 104b and the mask layer 117.

As shown in FIG. 3A-3, the first dummy gate structure 118a and the second dummy gate structure 118b are formed on the first fin structure 104a and the second fin structure 104b. The sacrificial layer 103 is directly below the stack layer including the first semiconductor material layers 106 and second semiconductor material layers 108.

As shown in FIG. 3A-4, the first dummy gate structure 118a and the second dummy gate structure 118b are formed on the isolation structure 116. The mask layer 117 is between the first dummy gate structure 118a and the isolation structure 116. The mask layer 117 is between the second dummy gate structure 118b and the isolation structure 116. In addition, the mask layer 117 is between the gate spacer layer 126 and the isolation structure 116.

FIG. 3B-1 illustrates the cross-sectional representation shown along line Y1-Y1′ in FIGS. 1E and 2E. FIG. 3B-2 illustrates the cross-sectional representation shown along line Y2-Y2′ in FIGS. 1E and 2E, in accordance with some embodiments. FIG. 3B-3 illustrates the cross-sectional representation shown along line X1-X1′ in FIGS. 1E and 2E. FIG. 3B-4 illustrates the cross-sectional representation shown along line X2-X2′ in FIGS. 1E and 2E. FIG. 2E shows the layout of the mask layer 117. Although the first dummy gate structure 118a, the second dummy gate structure 118b, the gate spacer layer 126 and the fin spacer layer 128 are formed on the mask layer 117, in order to show the layout of the mask layer 117, the first dummy gate structure 118a, the second dummy gate structure 118b, the gate spacer layer 126 and the fin spacer layer 128 become transparent when seen from a top-view.

Next, as shown in FIGS. 3B-1, 3B-2, 3B-3 and 3B-4, the source/drain (S/D) regions of the first fin structure 104a and the second fin structure 104b are recessed to form source/drain (S/D) recesses 130, in accordance with some embodiments. More specifically, the first semiconductor material layers 106 and the second semiconductor material layers 108 not covered by the dummy gate structures 118 and the gate spacer layers 126 are removed, in accordance with some embodiments. In addition, some portions of the base fin structure 105 are also recessed to form curved top surfaces, as shown in FIG. 3B-1, in accordance with some embodiments.

In some embodiments, the first fin structure 104a and the second fin structure 104b are recessed by performing an etching process. The etching process may be an anisotropic etching process, such as dry plasma etching, and the first dummy gate structure 118a, the second dummy gate structure 118b and the gate spacer layers 126 are used as etching masks during the etching process. In some embodiments, the fin spacer layers 128 are also recessed to form lowered fin spacer layers 128′.

Afterwards, as shown in FIGS. 3C-1, 3C-2, 3C-3 and 3C-4, the sacrificial layer 103 directly below the first dummy gate structure 118a and the second dummy gate structure 118b is removed to form trench 129, in accordance with some embodiments.

It should be noted that since the sacrificial layer 103 and the first semiconductor material layers 106 and the second semiconductor material layers 108 have etching selectivity, the first semiconductor material layers 106 and the second semiconductor material layers 108 are not removed while the sacrificial layer 103 is removed. In some embodiments, the sacrificial layer 103 is removed by etching process, such as dry etching process or wet etching process.

Afterwards, as shown in FIGS. 3D-1, 3D-2, 3D-3 and 3D-4, a dielectric layer 131 is formed in the trench 129, in accordance with some embodiments. As a result, the dielectric layer 131 is directly below the first fin structure 104a and the second fin structure 104b. The dielectric layer 131 is in direct contact with the bottommost first semiconductor material layers 106.

The dielectric layer 131 is made of silicon nitride (SiN), silicon oxide (SiOx), silicon oxynitride (SiON), silicon carbon nitride (SiCN), silicon oxide carbonitride (SiOCN), Silicon oxycarbide (SiCO), silicon carbide (SIC), high-k dielectric material (HfO or AlOx), or another applicable material. In some embodiments, the dielectric layer 131 is formed by chemical vapor deposition (CVD), ALD, other application methods, or a combination thereof.

Afterwards, as shown in FIGS. 3E-1, 3E-2, 3E-3 and 3E-4, after the dielectric layer 131 is formed, a portion of the first semiconductor material layers 106 exposed by the source/drain recesses 130 are laterally recessed to form notches 132, in accordance with some embodiments.

In some embodiments, an etching process is performed on the semiconductor structure 100a to laterally recess the first semiconductor material layers 106 of the fin structures 104a/104b from the source/drain recesses 130. In some embodiments, during the etching process, the first semiconductor material layers 106 have a greater etching rate (or etching amount) than the second semiconductor material layers 108, thereby forming notches 132 between adjacent second semiconductor material layers 108. In some embodiments, the etching process is an isotropic etching such as dry chemical etching, remote plasma etching, wet chemical etching, another suitable technique, and/or a combination thereof.

Next, as shown in FIGS. 3F-1, 3F-2, 3F-3 and 3F-4, inner spacers 133 are formed in the notches 132 between the second semiconductor material layers 108, in accordance with some embodiments. The inner spacers 133 are configured to separate the source/drain (S/D) structures and the gate structures formed in subsequent manufacturing processes in accordance with some embodiments.

In some embodiments, the inner spacers 133 are made of a dielectric material, such as silicon oxide (SiO₂), silicon nitride (SiN), silicon carbide (SIC), silicon oxynitride (SiON), silicon carbon nitride (SiCN), silicon oxide carbonitride (SiOCN), or a combination thereof. In some embodiments, the inner spacer layer 133 is formed by a deposition process, such as chemical vapor deposition (CVD) process, atomic layer deposition (ALD) process, another applicable process, or a combination thereof.

Afterwards, as shown in FIGS. 3G-1, 3G-2, 3G-3 and 3G-4, after the inner spacers 133 are formed, a bottom layer 134, a bottom isolation layer 135, and source/drain (S/D) structures 136 are sequentially formed in the S/D recesses 130, in accordance with some embodiments. The bottom layer 134 is filled into the bottom of the S/D trench 130. Next, the bottom isolation layer 135 is formed on the bottom layer 134. Next, the S/D structures 136 are formed on the bottom isolation layer 135. In other words, the bottom isolation layer 135 is directly below the S/D structures 136. The bottom isolation layer 135 is used to reduce the leakage of the semiconductor structure 100a.

As shown in FIG. 3G-1, the bottom isolation layer 135 is in direct contact with the lowered fin spacer layer 128′. The top surface of the bottom isolation layer 135 is lower than the top surface of the lowered fin spacer layer 128′. In addition, the top surface of the bottom isolation layer 135 is higher than the top surface of the mask layer 117. In some embodiments, the distance between the top surface of the bottom isolation layer 135 and the top surface of the mask layer 117 is in a range from about 2 to about 20 nm.

As shown in FIG. 3G-3, the bottom isolation layer 135 is in direct contact with the inner spacer layer 133. The top surface of the bottom isolation layer 135 is lower than the top surface of the bottommost inner spacer layer 133.

In some embodiments, the bottom layer 134 is an epi layer, such as un-doped Si, un-doped SiGe or a combination thereof. In some embodiments, the bottom layer 134 is formed by using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof.

In some embodiments, the bottom isolation layer 135 is made of silicon nitride (SiN), silicon oxide (SiOx), silicon oxynitride (SiON), silicon carbon nitride (SiCN), silicon oxide carbonitride (SiOCN), Silicon oxycarbide (SiCO), silicon carbide (SiC), high-k dielectric material (HfO or AlOx), or another applicable material. In some embodiments, the bottom dielectric layer 135 is formed by chemical vapor deposition (CVD), ALD, other application methods, or a combination thereof.

In some embodiments, the source/drain (S/D) structures 136 are formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the source/drain (S/D) structure 136 are made of any applicable material, such as Ge, Si, GaAs, AlGaAs, SiGe, GaAsP, SiP, SiC, SiCP, or a combination thereof.

In some embodiments, the source/drain (S/D) structures 136 are in-situ doped during the epitaxial growth process. For example, the source/drain (S/D) structure 136 may be the epitaxially grown SiGe doped with boron (B). For example, the source/drain (S/D) structure 136 may be the epitaxially grown Si doped with carbon to form silicon: carbon (Si: C) source/drain features, phosphorous to form silicon: phosphor (Si: P) source/drain features, or both carbon and phosphorous to form silicon carbon phosphor (SiCP) source/drain features. In some embodiments, the source/drain (S/D) structures 136 are doped in one or more implantation processes after the epitaxial growth process.

Afterwards, as shown in FIGS. 3H-1, 3H-2, 3H-3 and 3H-4, a contact etch stop layer (CESL) 138 is conformally formed to cover the S/D structures 136, and an interlayer dielectric (ILD) layer 140 is formed over the contact etch stop layers 138, in accordance with some embodiments.

As shown in FIG. 3H-4, since the isolation structure 116 may be slightly removed when forming the S/D recess 130, the bottom surface of the CESL 138 is lower than the bottom surface of the mask layer 117.

In some embodiments, the contact etch stop layer 138 is made of a dielectric materials, such as silicon nitride, silicon oxide, silicon oxynitride, another suitable dielectric material, or a combination thereof. The dielectric material for the contact etch stop layers 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

After the contact etch stop layer 138 and the ILD layer 140 are deposited, a planarization process such as CMP or an etch-back process may be performed until the gate electrode layers 120 of the dummy gate structures 118 are exposed, as shown in FIG. 3H-3 in accordance with some embodiments.

Afterwards, as shown in FIGS. 3I-1, 3I-2, 3I-3 and 3I-4, the first dummy gate structure 118a and the second dummy gate structure 118b are removed to form a trench 141, in accordance with some embodiments. As a result, the first fin structure 104a and the second fin structure 104b are exposed by the trench 141. As shown in FIG. 3I-4, the mask layer 117 is exposed by the trench 141.

The removal process may include one or more etching processes. For example, when the dummy gate electrode layer 122 is polysilicon, a wet etchant such as a tetramethylammonium hydroxide (TMAH) solution may be used to selectively remove the dummy gate electrode layer 122. Afterwards, the dummy gate dielectric layer 120 may be removed using a plasma dry etching, a dry chemical etching, and/or a wet etching.

Next, as shown in FIGS. 3J-1, 3J-2, 3J-3 and 3J-4, the first semiconductor material layers 106 are removed to form nanostructures 108′ (or channel layers 108′) with the second semiconductor material layers 108, in accordance with some embodiments. As a result, a number of gaps 143 are formed between the nanostructures 108′ (or channel layers 108′). In addition, the dielectric layer 131 is exposed by the gaps 143.

The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

Next, as shown in FIGS. 3K-1, 3K-2, 3K-3 and 3K-4, after the nanostructures 108′ are formed, a first gate structure 142a and a second gate structure 142b are formed to surround the nanostructures 108′ and over the isolation structure 116, in accordance with some embodiments. As shown in FIG. 3K-4, the first gate structure 142a and the second gate structure 142b are formed on the mask layer 117. The mask layer 117 is between the first gate structure 142a and the isolation structure 116. The mask layer 117 is between the second gate structure 142b and the isolation structure 116

After the nanostructures 108′ are formed, the first gate structure 142a and the second gate structure 142b are formed wrapped around the nanostructures 108′. The first gate structure 142a and the second gate structure 142b wrap around the nanostructures 108′ to form gate-all-around transistor structures in accordance with some embodiments. In some embodiments, the first gate structure 142a includes an interfacial layer 144, a gate dielectric layer 146, and a gate electrode layer 148. In some embodiments, the second gate structure 142b includes the interfacial layer 144, the gate dielectric layer 146, and the gate electrode layer 148.

In some embodiments, the interfacial layers 144 are oxide layers formed around the nanostructures 108′ and on the top of the base fin structure 105. In some embodiments, the interfacial layers 144 are formed by performing a thermal process.

In some embodiments, the gate dielectric layers 146 are formed over the interfacial layers 144, so that the nanostructures 108′ are surrounded (e.g. wrapped) by the gate dielectric layers 146. In addition, the gate dielectric layers 146 also cover the sidewalls of the gate spacers 126 and the inner spacers 133 in accordance with some embodiments. In some embodiments, the gate dielectric layers 146 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. In some embodiments, the gate dielectric layers 146 are formed using chemical vapor deposition (CVD), atomic layer deposition (ALD), another applicable method, or a combination thereof.

In some embodiments, the gate electrode layer 148 are made of one or more layers of conductive material, such as aluminum, copper, titanium, tantalum, tungsten, cobalt, molybdenum, tantalum nitride, nickel silicide, cobalt silicide, TIN, WN, TiAl, TiAlN, TaCN, TaC, TaSiN, metal alloys, another suitable material, or a combination thereof. In some embodiments, the gate electrode layer 148 are formed using chemical vapor deposition (CVD), atomic layer deposition (ALD), electroplating, another applicable method, or a combination thereof. Other conductive layers, such as work function metal layers, may also be formed in the gate electrode layer 148, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

After the interfacial layers 144, the gate dielectric layers 146, and the gate electrode layer 148 are formed, a planarization process such as CMP or an etch-back process may be performed until the ILD layer 140 is exposed.

Afterwards, as shown in FIGS. 3L-1, 3L-2, 3L-3 and 3L-4, an etch stop layer 150 is formed over the gate structure 142, and a dielectric layer 152 is formed over the etch stop layer 150, in accordance with some embodiments.

In some embodiments, the etch stop layer 150 is made of a dielectric materials, such as silicon nitride, silicon oxide, silicon oxynitride, another suitable dielectric material, or a combination thereof. The dielectric material for the etch stop layers 150 may be conformally deposited over the semiconductor structure by performing chemical vapor deposition (CVD), ALD, other application methods, or a combination thereof.

The dielectric layer 152 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 152 may be formed by chemical vapor deposition (CVD), physical vapor deposition, (PVD), atomic layer deposition (ALD), or other applicable processes.

Next, a silicide layer 154 and an S/D contact structure 156 are formed over the S/D structures 136, in accordance with some embodiments.

In some embodiments, the contact openings may be formed through the contact etch stop layer 138, the interlayer dielectric layer 140, the etch stop layer 150 and the dielectric layer 152 to expose the top surfaces of the S/D structure 136, and then the silicide layers 154 and the S/D contact structure 156 may be formed in the contact openings. The contact openings may be formed using a photolithography process and an etching process. In addition, some portions of the S/D structures 136 exposed by the contact openings may also be etched during the etching process.

The silicide layers 154 may be formed by forming a metal layer over the top surfaces of the S/D structure 136 and annealing the metal layer so the metal layer reacts with the S/D structure 136 to form the silicide layers 154. The unreacted metal layer may be removed after the silicide layers 154 are formed.

The S/D contact structure 156 may include a barrier layer and a conductive layer. In some other embodiments, the S/D contact structure 156 does not include a barrier layer. In some embodiments, the barrier layer is made of titanium (Ti), titanium nitride (TiN), tantalum (Ta), tantalum nitride (TaN), or another applicable material. In some embodiments, the barrier layer is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. In some embodiments, the conductive layer is made of tungsten (W), ruthenium (Ru), molybdenum (Mo), or the like. In some embodiments, the conductive layer is formed by performing a deposition process, such as chemical vapor deposition (CVD), physical vapor deposition, (PVD), atomic layer deposition (ALD), or other applicable processes.

After the S/D contact structure 156 are formed, an etch stop layer 162 is formed over the S/D contact structure 156, and a dielectric layer 164 is formed over the etch stop layer 162, in accordance with some embodiments. Next, a S/D conductive via 166 is formed over the S/D contact structure 156, and a gate conductive plug 168 is formed over the first gate structure 142a and the second gate structure 142b.

A front end structure 170 is constructed by the etch stop layer 150, the dielectric layer 152, the S/D contact structure 156, the etch stop layer 162, the dielectric layer 164, the S/D conductive plug 166 and the gate conductive plug 168.

In some embodiments, the etch stop layer 162 is made of a dielectric materials, such as silicon nitride, silicon oxide, silicon oxynitride, another suitable dielectric material, or a combination thereof. The dielectric material for the contact etch stop layers 162 may be conformally deposited over the semiconductor structure by performing chemical vapor deposition (CVD), atomic layer deposition (ALD), other application methods, or a combination thereof.

The dielectric layer 164 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 164 may be formed by chemical vapor deposition (CVD), physical vapor deposition, (PVD), atomic layer deposition (ALD), or other applicable processes.

In some embodiments, the S/D conductive via 166 is made of conductive material, such as tungsten (W), ruthenium (Ru), molybdenum (Mo), or the like. In some embodiments, the S/D conductive via 166 is formed by performing a deposition process, such as chemical vapor deposition (CVD), physical vapor deposition, (PVD), atomic layer deposition (ALD), or other applicable processes.

In some embodiments, the gate conductive plug 168 is made of conductive material, such as tungsten (W), ruthenium (Ru), molybdenum (Mo), or the like. In some embodiments, the gate conductive plug 168 is formed by performing a deposition process, such as chemical vapor deposition (CVD), physical vapor deposition, (PVD), atomic layer deposition (ALD), or other applicable processes.

Next, as shown in FIGS. 3M-1, 3M-2, 3M-3 and 3M-4, after the front end structure 170 is formed, a carrier substrate (not shown) is attached to the front end structure 170, and then the substrate 102 is turned upside down, and a planarization is performed on the back side of the substrate 102, in accordance with some embodiments. More specifically, a planarization is performed on the substrate 102 until the isolation structure 116 is exposed. The planarization process may be an etching process, a CMP process, a mechanical grinding process, a dry polishing process, or a combination thereof.

Afterwards, as shown in FIGS. 3N-1, 3N-2, 3N-3 and 3N-4, after a portion of the substrate 102 is removed, and a dielectric layer 174 is formed over the isolation structure 116, in accordance with some embodiments.

The dielectric layer 174 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 174 may be formed by chemical vapor deposition (CVD), physical vapor deposition, (PVD), atomic layer deposition (ALD), or other applicable processes.

Next, as shown in FIGS. 3O-1, 3O-2, 3O-3 and 3O-4, a back-side contact structure 178 is formed through the dielectric layer 174, the substrate 102, the bottom layer 134, the bottom isolation layer 135, the S/D structure 136, in accordance with some embodiments. More specifically, the back-side contact structure 178 is formed through the bottom isolation layer 135 and the bottom portion of the S/D structure 136.

A trench is formed through the dielectric layer 174, the substrate 102, the bottom layer 134, the bottom isolation layer 135, a portion of the S/D structure 136, and a conductive material is formed in the trench to form back-side contact structure 178.

It should be noted that the dielectric layer 131 is directly under the nanostructures 108′, the first gate structure 142a and the second gate structure 142b, the first gate structure 142a and the second gate structure 142b are protected by the dielectric layer 131. Therefore, the dielectric layer 131 is used as an etch stop layer to prevent the nanostructures 108′, the first gate structure 142a and the second gate structure 142b from being damaged by the etching process for forming the trench for the back-side contact structure 178. In addition, the unwanted leakage between the back-side contact structure 178 and the first gate structure 142a and the second gate structure 142b are reduced. Therefore, the performance of the semiconductor structure 100a is improved by forming the dielectric layer 131 directly below the first gate structure 142a and the second gate structure 142b.

Furthermore, the dielectric layer 131 is directly under the nanostructures 108′, rather than a Si base fin structure 105, the unwanted leakage or parasitic capacitance between nanostructures 108′ and the Si base fin structures 105 can be reduced. Therefore, the performance of the semiconductor structure 100a is improved by forming the dielectric layer 131 directly below the nanostructures 108′.

In addition, the mask layer 117 is formed on the isolation structure 116. The mask layer 117 is used as an etch stop layer to protect the isolation structure 116. When performing the step of forming the gaps 143 (shown in FIGS. 3J-2 and 3J-3), the isolation structure 116 may be removed by the etching process, the mask layer 117 is used to prevent the isolation structure 116 from being etched or damaged. If the isolation structure 116 is removed by the etching process, the first gate structure 142a and the second gate structure 142b are formed deeper than expected. The performance of the semiconductor structure 100a may be degraded by forming the deep first gate structure 142a and the second gate structure 142b. Therefore, the unwanted capacitance generated from the deep first gate structure 142a and the second gate structure 142b can be reduced. The performance of the semiconductor structure 100a is improved by forming the mask layer 117 on the isolation structure.

It should be noted that the trench, as it is formed, passes through the bottom isolation layer 135, but not the dielectric layer 131. The dielectric layer 131 and the bottom isolation layer 135 are made of different materials. The dielectric layer 131 has a high etching selectively with respect to the bottom isolation layer 135, and therefore the dielectric layer 131 is not removed while the bottom isolation layer 135 is removed.

Furthermore, the mask layer 117 and the bottom isolation layer 135 are made of different materials. The mask layer 117 has a high etching selectively with respect to the bottom isolation layer 135, and therefore the mask layer 117 is not removed while the bottom isolation layer 135 is removed.

The back-side contact structure 178 is surrounded by a barrier layer 179. The barrier layer is used to reduce the leakage. In some other embodiments, the back-side contact structure 178 is not surrounded by barrier layer. In some embodiments, the barrier layer 179 is made of titanium (Ti), titanium nitride (TiN), tantalum (Ta), tantalum nitride (TaN), silicon nitride (SiN), silicon oxide (SiOx), silicon oxynitride (SiON), silicon carbon nitride (SiCN), silicon oxide carbonitride (SiOCN), Silicon oxycarbide (SiCO), silicon carbide (SiC), high-k material (HfO or AlOx), or another applicable material.

In some embodiments, the barrier layer 179 is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

In some embodiments, the back-side contact structure 178 is made of tungsten (W), ruthenium (Ru), molybdenum (Mo), or the like. In some embodiments, the back-side contact structure 178 is formed by performing a deposition process, such as chemical vapor deposition (CVD), physical vapor deposition, (PVD), atomic layer deposition (ALD), or other applicable processes.

FIG. 4 illustrates a top view of the semiconductor structure 100a, in accordance with some embodiments. Some elements are not shown in FIG. 4 for clarity.

The first fin structure 104a and the second fin structure 104b are formed along a first direction (e.g. X-axis), and the first gate structure 142a and the second gate structure 142b are formed along a second direction (e.g. Y-axis). The first fin structure 104a and the second fin structure 104b includes a number of the nanostructures 108′. The first direction is orthogonal to the second direction. The gate spacer layers 128 are formed on opposite sidewall surfaces of the first gate structure 142a and the second gate structure 142b. The fin spacer layers 128 are formed on opposite sidewall surfaces of the first fin structure 104a and the second fin structure 104b.

The mask layer 117 is directly below the first gate structure 142a and the second gate structure 142b, the gate spacer layer 126 and the fin spacer layer 128. The mask layer 117 protects the isolation structure 116 from being etched or damaged. In addition, the mask layer 117 protect the first gate structure 142a and the second gate structure 142b when forming the back-side contact structure 178.

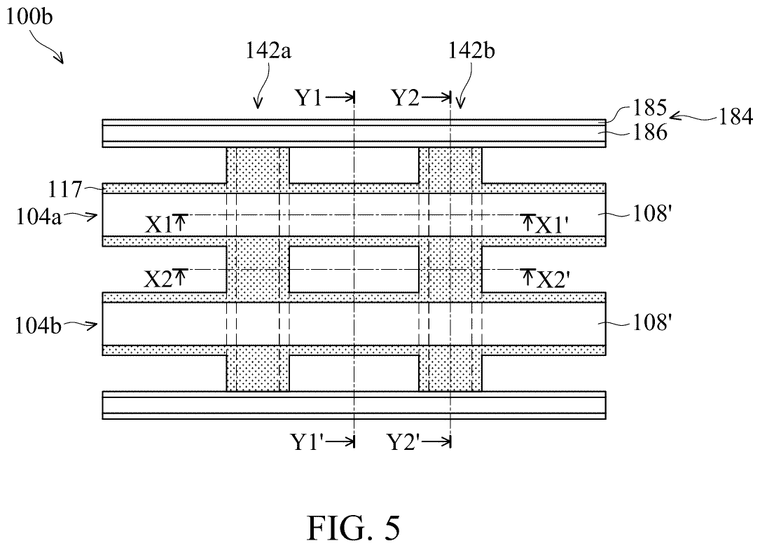

FIG. 5 illustrates a top view of a semiconductor structure 100b, in accordance with some embodiments. The semiconductor structure 100b of FIG. 5 includes elements that are similar to, or the same as, elements of the semiconductor structure 100a of FIG. 1E, the difference between the FIG. 5 and FIG. 4 is that a dielectric wall structure 184 is formed along the first direction (e.g. X-axis). The dielectric wall structure 184 is used to cut or separate the first gate structure 142a and the second gate structure 142b.

The dielectric wall structure 184 includes a liner layer 185 and a dielectric layer 186 surrounded by the liner layer. The dielectric wall structure 184 is formed by forming a trench (not shown) in the first direction (e.g. x-axis), and the trench is through the ILD layer 140, the first gate structure 142a, the second gate structure 142b, the CESL 138, the mask layer 117 and the isolation structure 116. Next, the liner layer 185 is formed in the trench, and then the dielectric layer 186 is formed on the liner layer 185.

In some embodiments, the liner layer 185 is made of silicon nitride. In some embodiments, the liner layer 185 is formed by a chemical vapor deposition (CVD), a physical vapor deposition, (PVD), an atomic layer deposition (ALD), or other applicable processes.

In some embodiments, the dielectric layer 186 is made of silicon nitride (SiN), silicon oxide (SiOx), silicon oxynitride (SiON), silicon carbon nitride (SiCN), silicon oxide carbonitride (SiOCN), Silicon oxycarbide (SiCO), silicon carbide (SiC), and/or a combination thereof. In some embodiments, the dielectric layer 186 is formed by a chemical vapor deposition (CVD), a physical vapor deposition, (PVD), an atomic layer deposition (ALD), or other applicable processes.

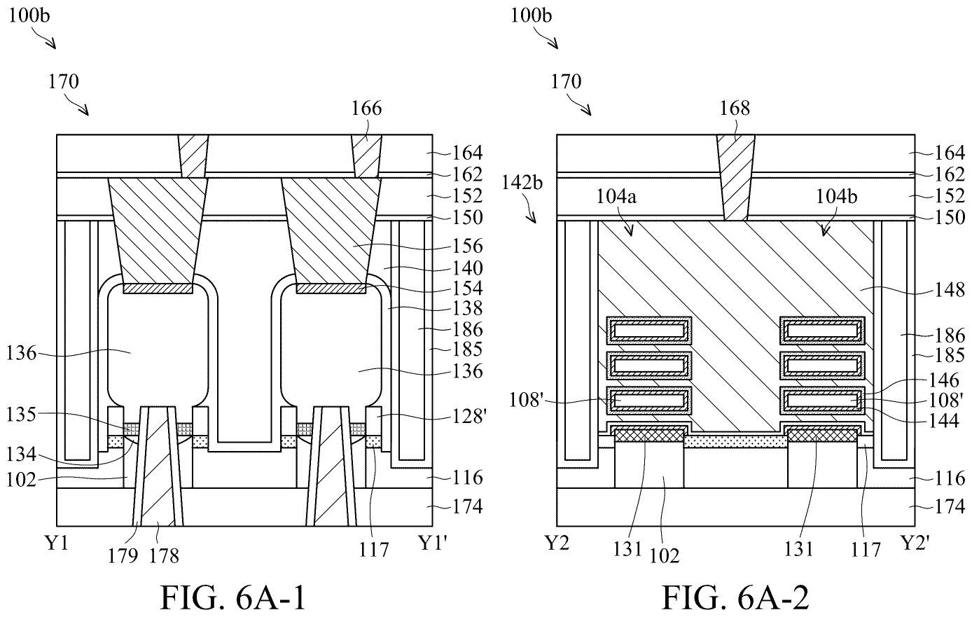

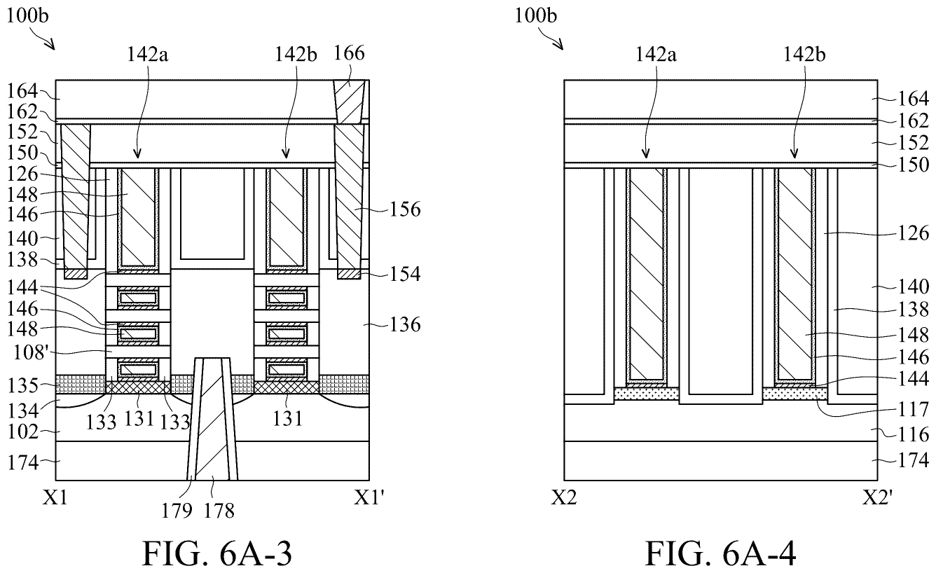

FIG. 6A-1 illustrates the cross-sectional representation shown along line Y1-Y1′ in FIG. 5, in accordance with some embodiments. FIG. 6A-2 illustrates the cross-sectional representation shown along line Y2-Y2′ in FIG. 5, in accordance with some embodiments. FIG. 6A-3 illustrates the cross-sectional representation shown along line X1-X1′ in FIG. 5, in accordance with some embodiments. FIG. 6A-4 illustrates the cross-sectional representation shown along line X2-X2′ in FIG. 5, in accordance with some embodiments.

As shown in FIGS. 6A-1 and 6A-2, the dielectric wall structures 184 are between two adjacent S/D structures 136. The dielectric wall structures 184 are formed on two ends of the second gate structure 142b.

The bottom surface of the dielectric wall structure 184 is lower than the bottom surface of the mask layer 117. The bottom surface of the dielectric wall structure 184 is lower than the bottom surface of dielectric layer 131. The bottom surface of the dielectric wall structure 184 is lower than the bottom surface of the bottom isolation layer 135. In addition, the bottom surface of the dielectric wall structure 184 is lower than the top surface of the isolation structure 116. The top surface of the dielectric wall structure 184 is substantially coplanar with the top surfaces of the first gate structure 142a and the second gate structure 142b.

FIG. 6A-3 is similar to, or the same as FIG. 3O-3. FIG. 6A-4 is similar to, or the same as FIG. 3O-4.

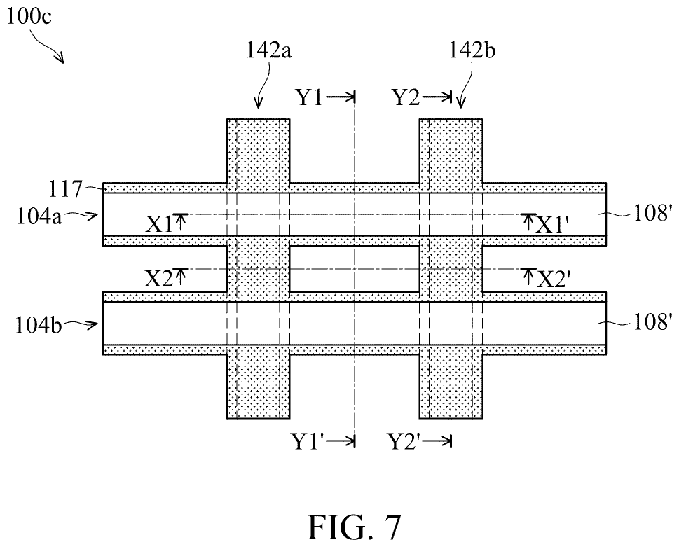

FIG. 7 illustrates a perspective view of a semiconductor structure 100c, in accordance with some embodiments. The semiconductor structure 100c of FIG. 7 includes elements that are similar to, or the same as, elements of the semiconductor structure 100a of FIG. 4, the difference between the FIG. 7 and FIG. 4 is that back-side contact structure 178 is shifted or misaligned.

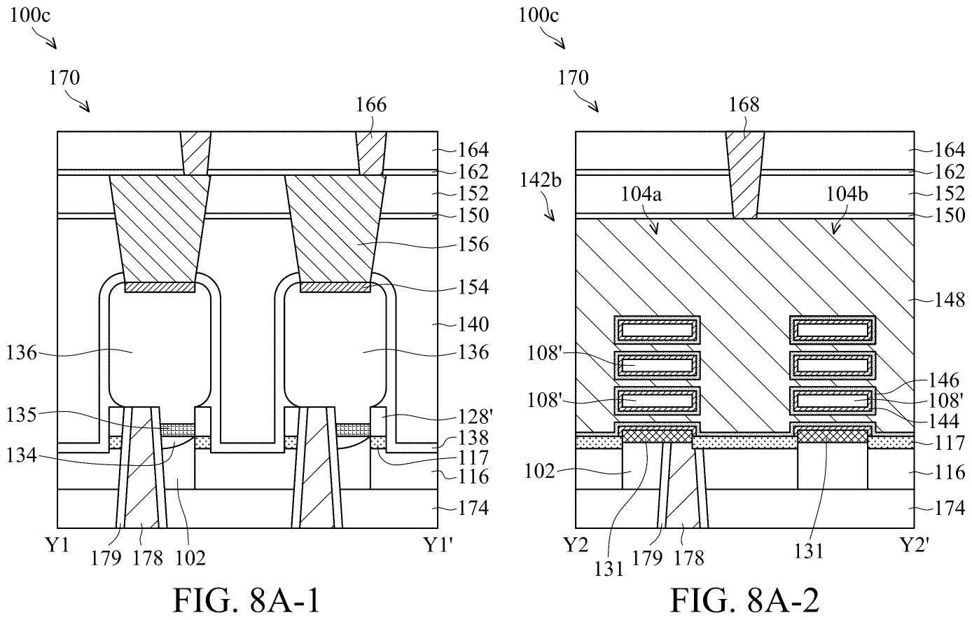

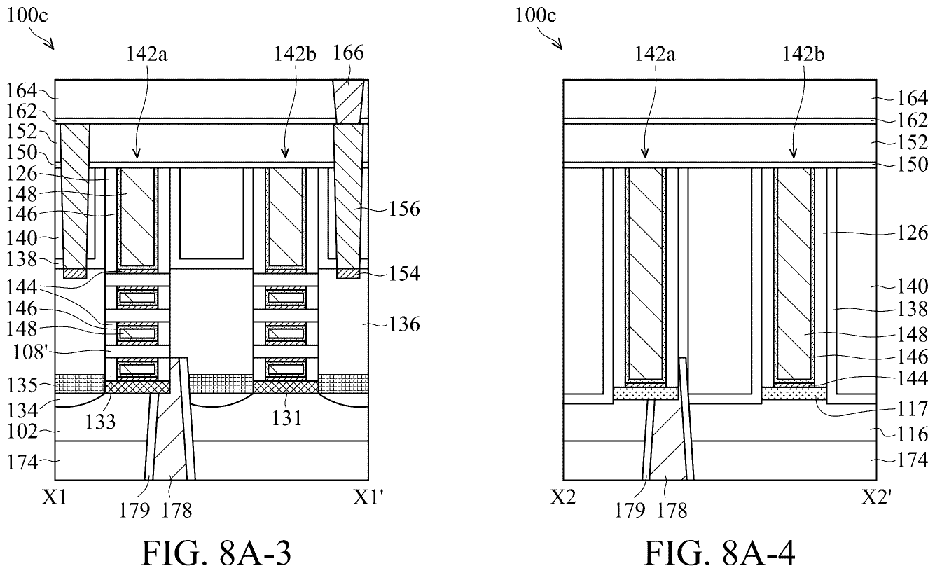

FIG. 8A-1 illustrates the cross-sectional representation shown along line Y1-Y1′ in FIG. 7, in accordance with some embodiments. FIG. 8A-2 illustrates the cross-sectional representation shown along line Y2-Y2′ in FIG. 7, in accordance with some embodiments. FIG. 8A-3 illustrates the cross-sectional representation shown along line X1-X1′ in FIG. 7, in accordance with some embodiments. FIG. 8A-4 illustrates the cross-sectional representation shown along line X2-X2′ in FIG. 7, in accordance with some embodiments.

As shown in FIG. 8A-1, the back-side contact structure 178 penetrates the bottom isolation layer 135, but not the mask layer 117. The mask layer 117 and the bottom isolation layer 135 are made of different materials. The mask layer 117 has a high etching selectivity with respect to the bottom isolation layer 135, and therefore the mask layer 117 is not removed when the bottom isolation layer 135 is removed.

The back-side contact structure 178 is in direct contact with the S/D structure 136. The back-side contact structure 178 is electrically connected to the S/D structure 136. The top surface of the back-side contact structure 178 is higher than the top surface of the bottom isolation layer 135. In some embodiments, the top surface of the back-side contact structure 178 is higher than the top surface of the lowered fin spacer layer 128′.

As shown in FIG. 8A-2, the back-side contact structure 178 is not through the mask layer 117 and the dielectric layer 131. The mask layer 117 and the dielectric layer 131 are used as etch stop layer when forming the trench of back-side contact structure 178. The top surface of the back-side contact structure 178 is in direct contact with the bottom surface of the mask layer 117. Therefore, the back-side contact structure 178 is not direct contact with the second gate structure 142b.

As shown in FIG. 8A-3, the back-side contact structure 178 passes through the bottom isolation layer 135, but not the dielectric layer 131. A portion of the back-side contact structure 178 extends into the S/D structure 136, but another portion of the back-side contact structure 178 stops at the dielectric layer 131.

As shown in FIG. 8A-4, the back-side contact structure 178 passes through the CESL 138, but not the mask layer 117. A portion of the back-side contact structure 178 extends into the CESL 138, and therefore a portion of the back-side contact structure 178 is in direct contact with the gate spacer layer 126.

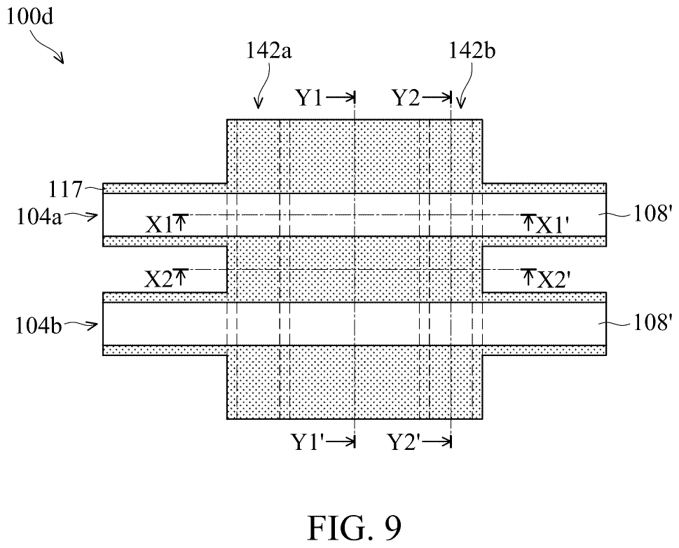

FIG. 9 illustrates a perspective view of a semiconductor structure 100d, in accordance with some embodiments. The semiconductor structure 100d of FIG. 9 includes elements that are similar to, or the same as, elements of the semiconductor structure 100a of FIG. 4, the difference between the FIG. 9 and FIG. 4 is that the mask layer 117 is formed under the S/D structure 136, the first gate structure 142a, the second gate structure 142b, the gate spacer layer 126 and the fin spacer layer 128. The mask layer 117 extends from the gate region to the S/D region. The mask layer 117 at the S/D region is not removed when forming the S/D recess 130.

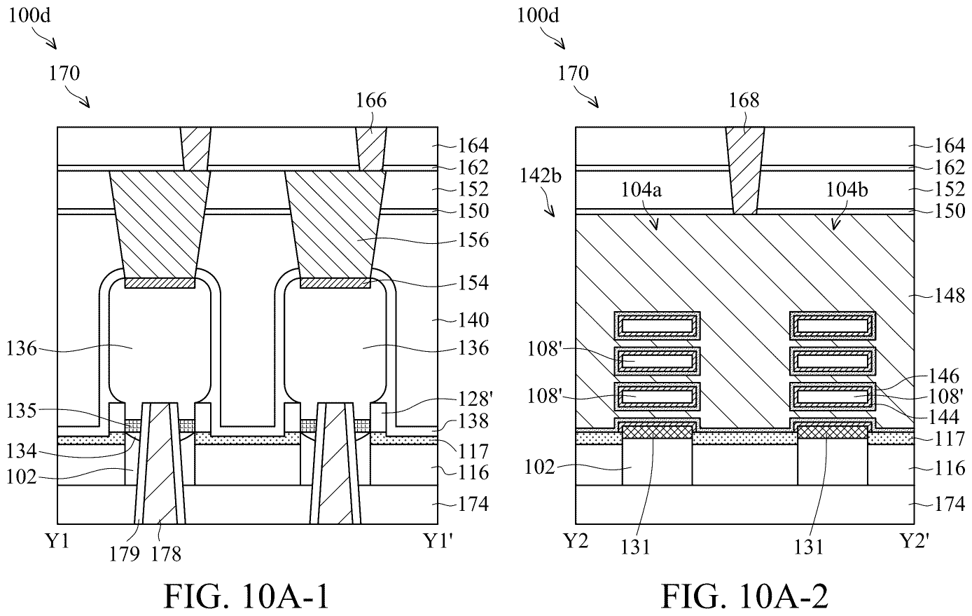

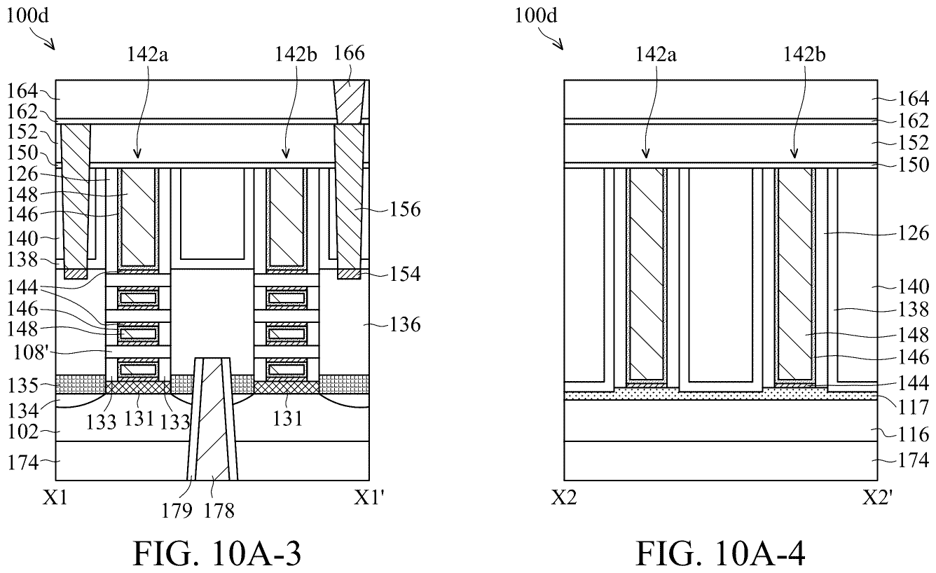

FIG. 10A-1 illustrates the cross-sectional representation shown along line Y1-Y1′ in FIG. 9, in accordance with some embodiments. FIG. 10A-2 illustrates the cross-sectional representation shown along line Y2-Y2′ in FIG. 9, in accordance with some embodiments. FIG. 10A-3 illustrates the cross-sectional representation shown along line X1-X1′ in FIG. 9, in accordance with some embodiments. FIG. 10A-4 illustrates the cross-sectional representation shown along line X2-X2′ in FIG. 9, in accordance with some embodiments.

As shown in FIG. 10A-1, the mask layer 117 is directly below the CESL 138 and the ILD layer 140. The mask layer 117 is in direct contact with the CESL 138. In addition, the mask layer 117 is directly below the lowered fin spacer layer 128′.

FIG. 10A-2, is similar to, or the same as FIG. 3O-2. FIG. 10A-3, is similar to, or the same as FIG. 3O-3.

As shown in FIG. 10A-4, the mask layer 117 is directly below the CESL 138 and the ILD layer 140. In addition, the mask layer 117 is directly below the first gate structure 142a, the second gate structure 142b and the gate spacer layer 126. The mask layer has a different thickness at different regions. In some embodiments, the thickness of the first portion of the mask layer 117 which is directly below the gate spacer layer 126 is greater than the thickness of the second portion of the mask layer 117 which is directly below the S/D region or the CESL 138. In some embodiments, the thickness of the first portion of the mask layer 117 which is directly below the first gate structure 142a is greater than the thickness of the first portion of the mask layer 117 which is directly below the S/D region or the CESL 138.

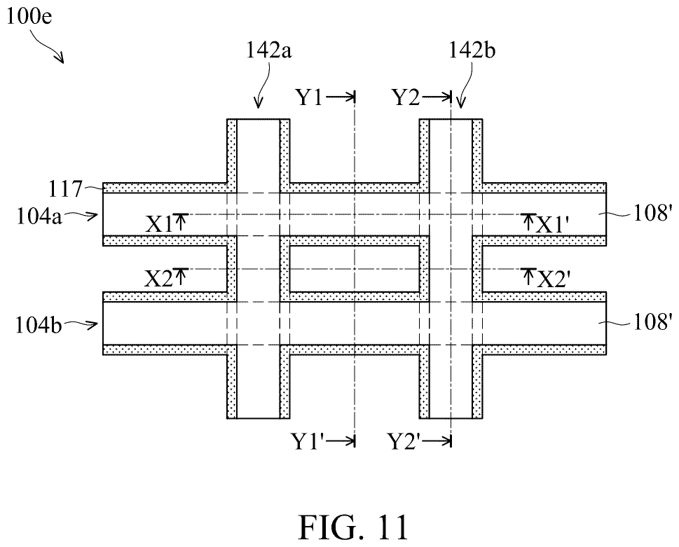

FIG. 11 illustrates a perspective view of a semiconductor structure 100e, in accordance with some embodiments. The semiconductor structure 100e of FIG. 11 includes elements that are similar to, or the same as, elements of the semiconductor structure 100a of FIG. 4, the difference between the FIG. 11 and FIG. 4 is that the mask layer 117 is directly below the gate spacer layer 126 and the lowered fin spacer layer 128′, not directly below the first gate structure 142a and the second gate structure 142b. The mask layer 117 which is directly below the first dummy gate structure 118a and the second dummy gate structure 118b are removed when the first dummy gate structure 118a and the second dummy gate structure 118b are removed (as shown in FIGS. 3I-2 and 3I-3).

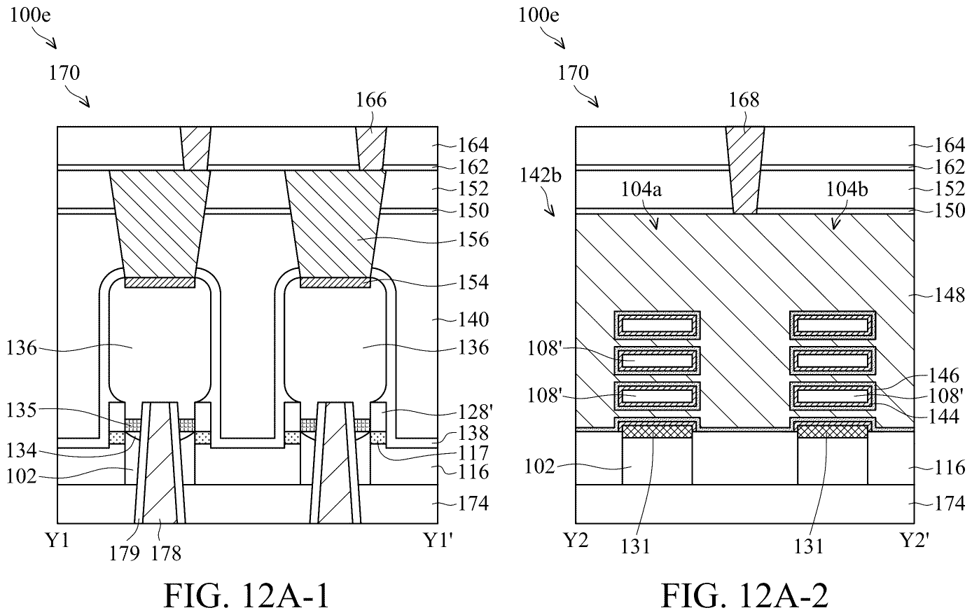

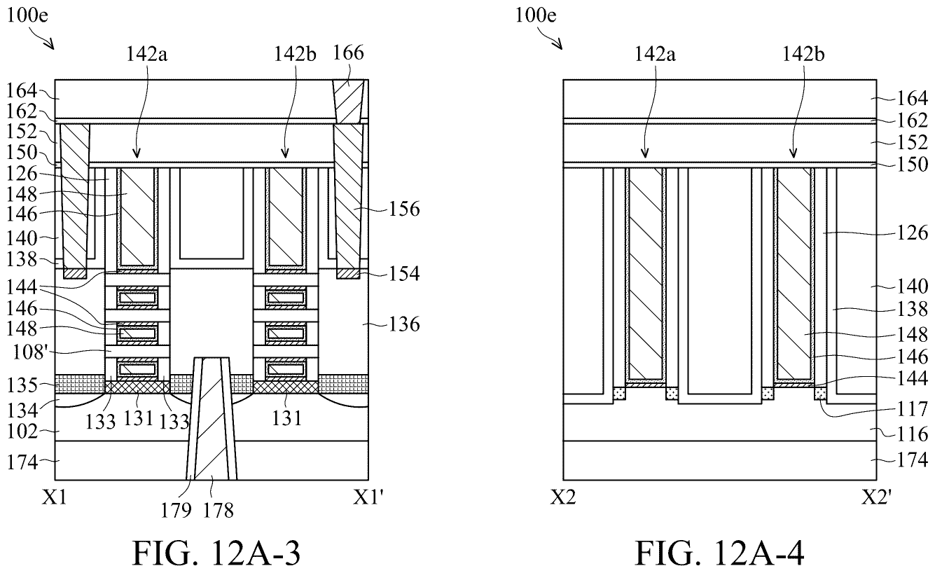

FIG. 12A-1 illustrates the cross-sectional representation shown along line Y1-Y1′ in FIG. 11, in accordance with some embodiments. FIG. 12A-2 illustrates the cross-sectional representation shown along line Y2-Y2′ in FIG. 11, in accordance with some embodiments. FIG. 12A-3 illustrates the cross-sectional representation shown along line X1-X1′ in FIG. 11, in accordance with some embodiments. FIG. 12A-4 illustrates the cross-sectional representation shown along line X2-X2′ in FIG. 11, in accordance with some embodiments.

FIG. 12A-1, is similar to, or the same as FIG. 3O-1.

As shown in FIG. 12A-2, the mask layer 117 is not directly below the first gate structure 142a and the second gate structure 142b. There is no mask layer between the isolation structure 116 and the first gate structure 142a. There is no mask layer between the isolation structure 116 and the second gate structure 142b.

FIG. 12A-3, is similar to, or the same as FIG. 3O-3.

As shown in FIG. 12A-4, the mask layer 117 is directly below the gate spacer layer 126, but not directly below the first gate structure 142a and the second gate structure 142b.

FIG. 13 illustrates a perspective view of a semiconductor structure 100f, in accordance with some embodiments. The semiconductor structure 100f of FIG. 13 includes elements that are similar to, or the same as, elements of the semiconductor structure 100a of FIG. 4, the difference between the FIG. 13 and FIG. 4 is that the mask layer 117 is not formed below the lowered fin spacer layer 128′.

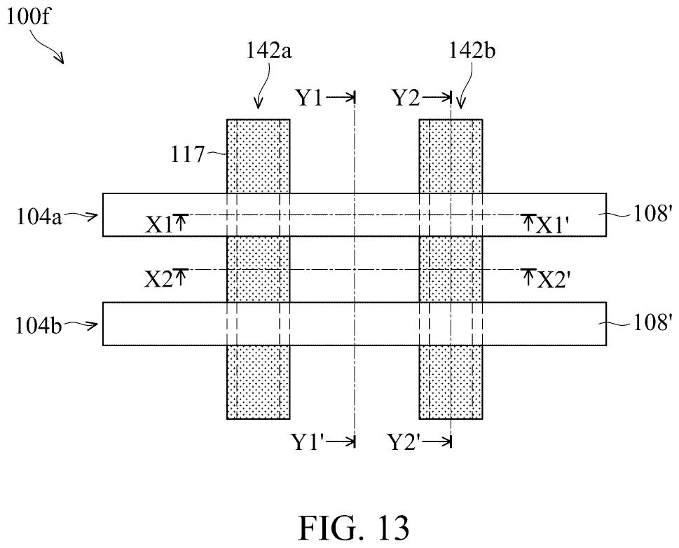

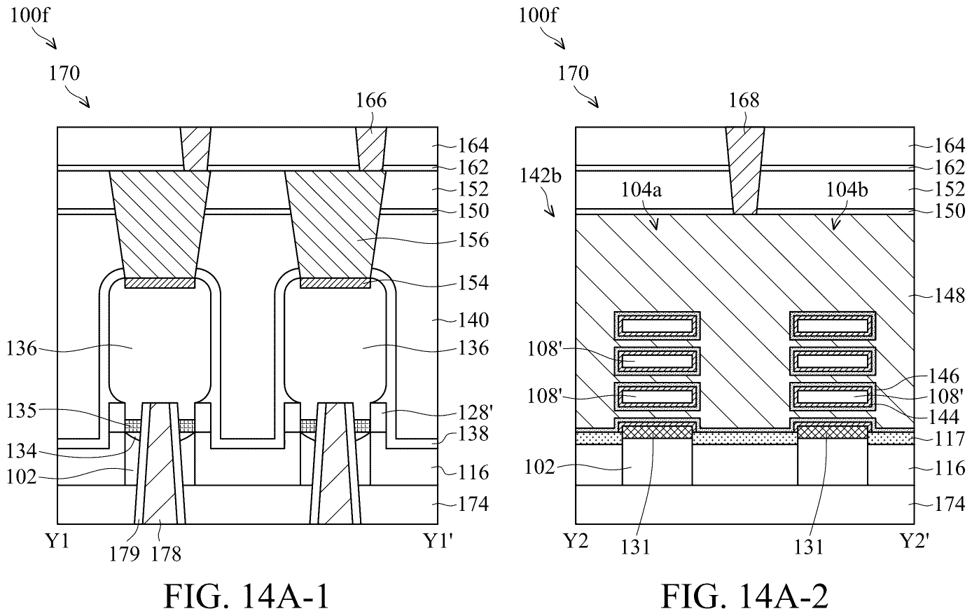

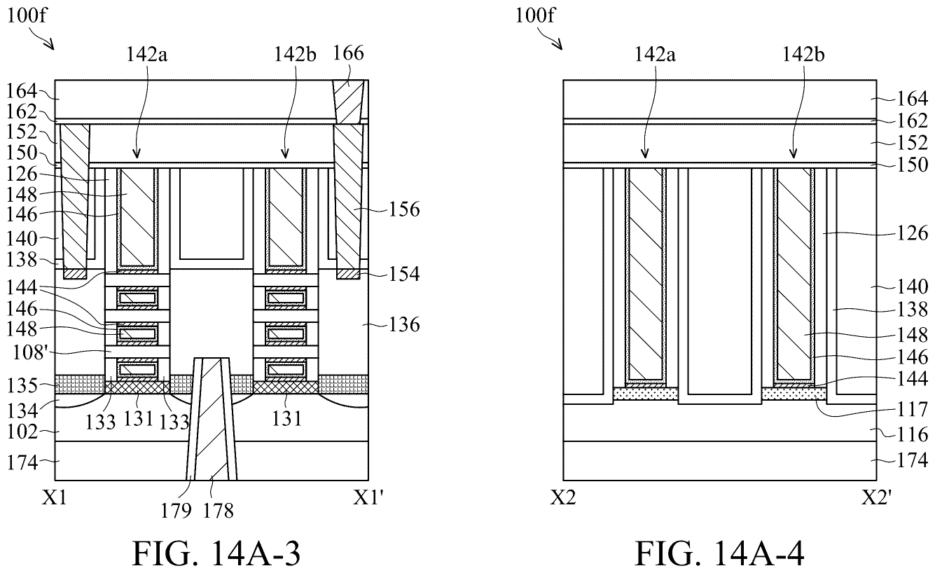

FIG. 14A-1 illustrates the cross-sectional representation shown along line Y1-Y1′ in FIG. 13, in accordance with some embodiments. FIG. 14A-2 illustrates the cross-sectional representation shown along line Y2-Y2′ in FIG. 13, in accordance with some embodiments. FIG. 14A-3 illustrates the cross-sectional representation shown along line X1-X1′ in FIG. 13, in accordance with some embodiments. FIG. 14A-4 illustrates the cross-sectional representation shown along line X2-X2′ in FIG. 13, in accordance with some embodiments.

As shown in FIG. 14A-1, the mask layer 117 is not directly below the lowered fin spacer layer 128′. A portion of the CESL 138 is lower than the bottom isolation layer 135.

FIG. 14A-2, is similar to, or the same as FIG. 3O-2. FIG. 14A-3, is similar to, or the same as FIG. 3O-3. FIG. 14A-4, is similar to, or the same as FIG. 3O-4.

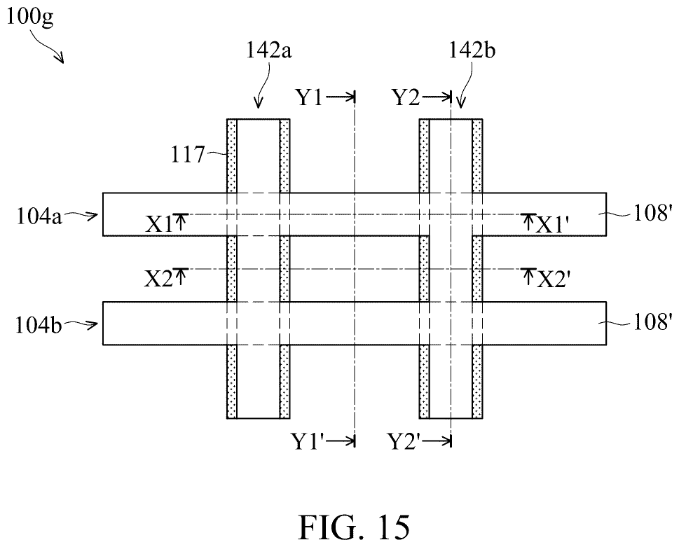

FIG. 15 illustrates a perspective view of a semiconductor structure 100g, in accordance with some embodiments. The semiconductor structure 100g of FIG. 15 includes elements that are similar to, or the same as, elements of the semiconductor structure 100e of FIG. 11, the difference between the FIG. 15 and FIG. 11 is that the mask layer 117 is not formed below the lowered fin spacer layer 128′.

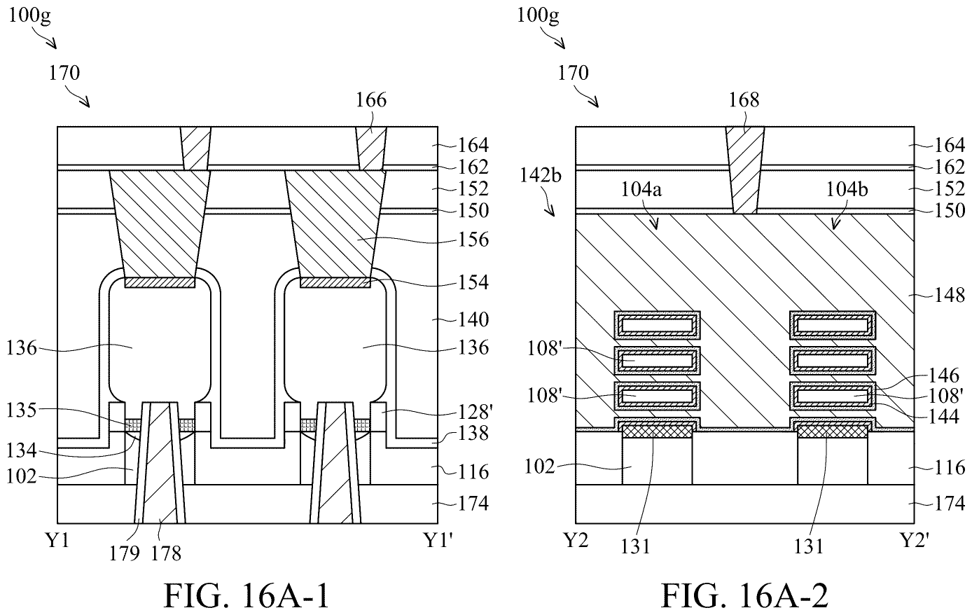

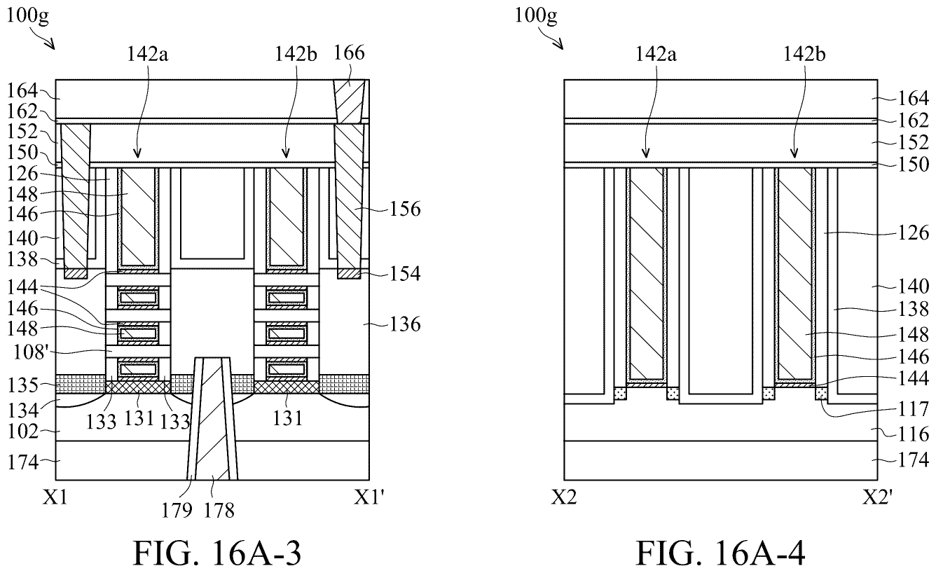

FIG. 16A-1 illustrates the cross-sectional representation shown along line Y1-Y1′ in FIG. 15, in accordance with some embodiments. FIG. 16A-2 illustrates the cross-sectional representation shown along line Y2-Y2′ in FIG. 15, in accordance with some embodiments. FIG. 16A-3 illustrates the cross-sectional representation shown along line X1-X1′ in FIG. 15, in accordance with some embodiments. FIG. 16A-4 illustrates the cross-sectional representation shown along line X2-X2′ in FIG. 15, in accordance with some embodiments.

FIG. 16A-1, is similar to, or the same as FIG. 14A-1. FIG. 16A-2, is similar to, or the same as FIG. 12A-2. FIG. 16A-3, is similar to, or the same as FIG. 14A-3. FIG. 16A-4, is similar to, or the same as FIG. 12A-4.

FIG. 17 illustrates a perspective view of a semiconductor structure 100h, in accordance with some embodiments. The semiconductor structure 100h of FIG. 17 includes elements that are similar to, or the same as, elements of the semiconductor structure 100a of FIG. 4, the difference between the FIG. 17 and FIG. 4 is that the shape of the back-side contact structure 178 has T-shaped structure.

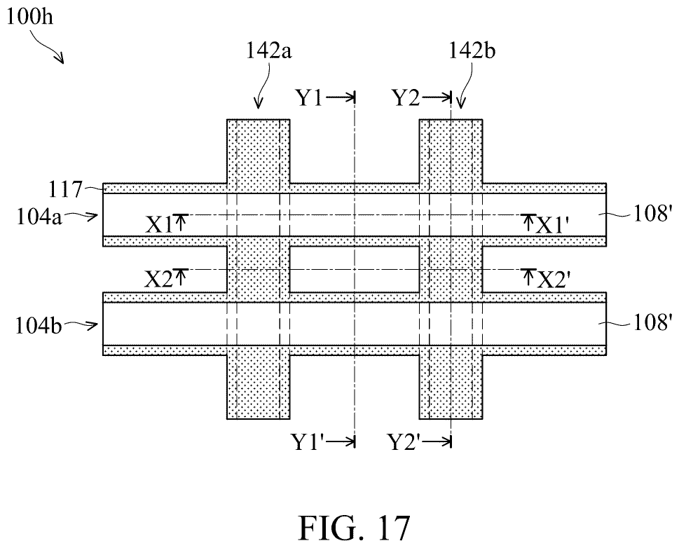

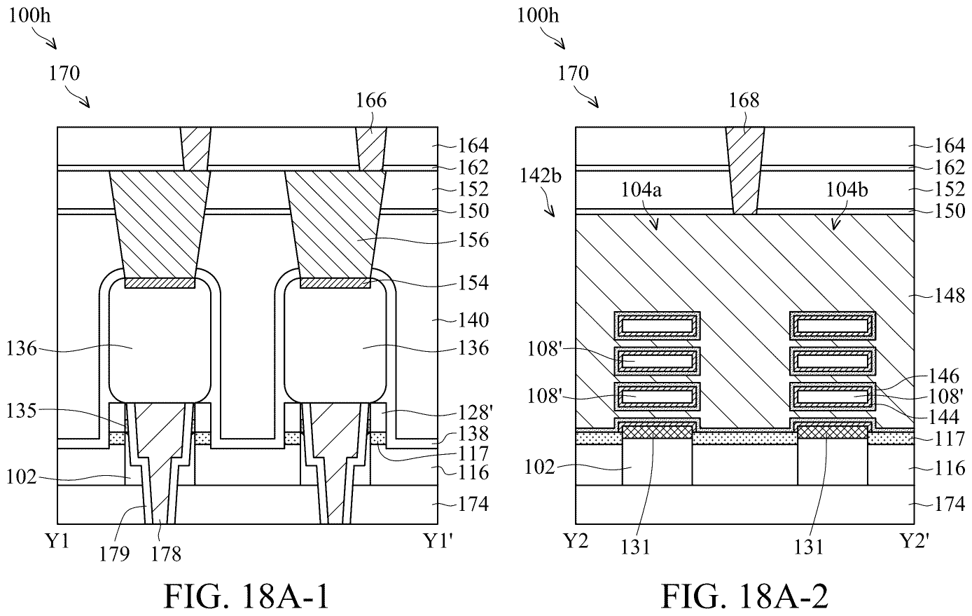

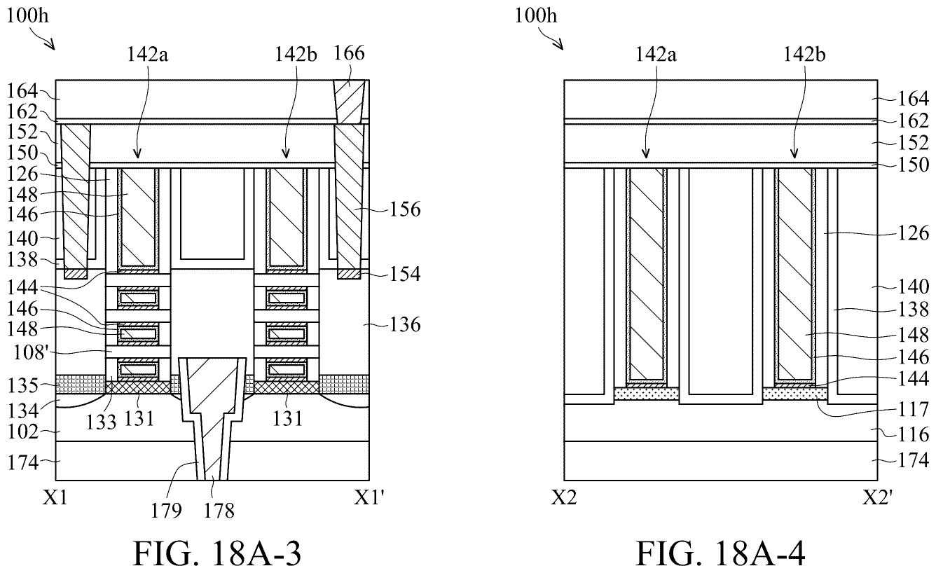

FIG. 18A-1 illustrates the cross-sectional representation shown along line Y1-Y1′ in FIG. 17, in accordance with some embodiments. FIG. 18A-2 illustrates the cross-sectional representation shown along line Y2-Y2′ in FIG. 17, in accordance with some embodiments. FIG. 18A-3 illustrates the cross-sectional representation shown along line X1-X1′ in FIG. 17, in accordance with some embodiments. FIG. 18A-4 illustrates the cross-sectional representation shown along line X2-X2′ in FIG. 17, in accordance with some embodiments.

As shown in FIG. 18A-1, the bottom layer 134 is formed in the S/D recess 130, and the bottom isolation layer 135 is formed on the bottom layer 134. In some embodiments, the bottom layer 134 is made of SiGe. Since the fin structure is made of Si, the bottom layer 134 (SiGe) with respect to the Si fin structure has high etching selectivity, the profile of the back-side contact structure 178 become T-shaped structure. The back-side contact structure 178 is through the bottom layer 134 and the bottom isolation layer 135 to form the T-shaped structure.

FIG. 18A-2, is similar to, or the same as FIG. 3O-2. FIG. 18A-4, is similar to, or the same as FIG. 3O-4.

As shown in FIG. 18A-4, the bottom layer 134 is formed in the S/D recess 130, and the bottom isolation layer 135 is formed on the bottom layer 134. In some embodiments, the bottom layer 134 is made of SiGe. Since the fin structure is made of Si, the bottom layer with respect to the Si fin structure has high etching selectivity, the profile of the back-side contact structure 178 become T-shaped structure. The back-side contact structure 178 is through the bottom layer 134 and the bottom isolation layer 135 to form the T-shaped structure.

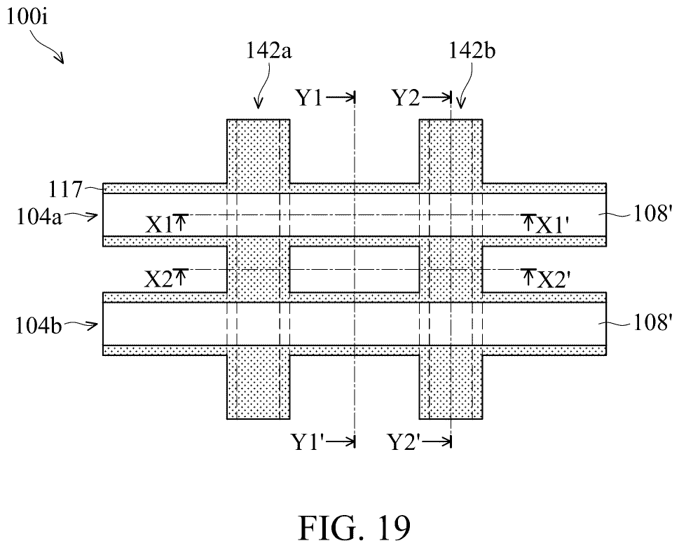

FIG. 19 illustrates a perspective view of a semiconductor structure 100i, in accordance with some embodiments. The semiconductor structure 100i of FIG. 19 includes elements that are similar to, or the same as, elements of the semiconductor structure 100h of FIG. 17, the difference between the FIG. 19 and FIG. 17 is that the shape of the back-side contact structure 178 has reversed T-shaped structure.

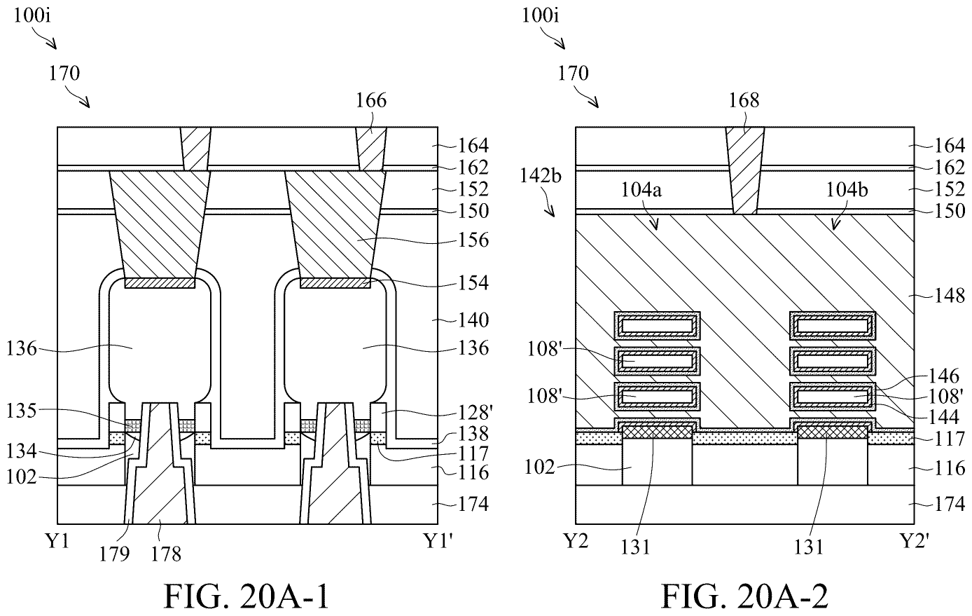

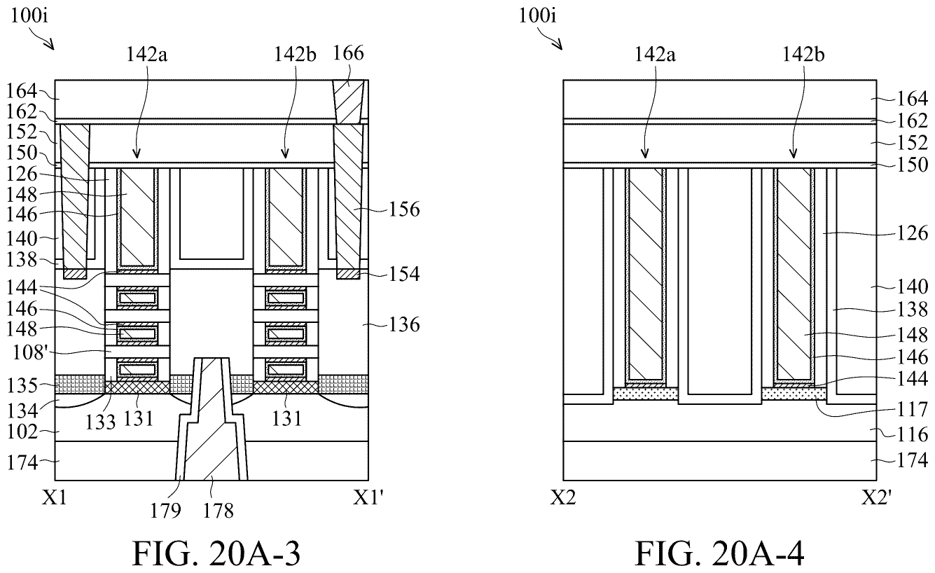

FIG. 20A-1 illustrates the cross-sectional representation shown along line Y1-Y1′ in FIG. 19, in accordance with some embodiments. FIG. 20A-2 illustrates the cross-sectional representation shown along line Y2-Y2′ in FIG. 19, in accordance with some embodiments. FIG. 20A-3 illustrates the cross-sectional representation shown along line X1-X1′ in FIG. 19, in accordance with some embodiments. FIG. 20A-4 illustrates the cross-sectional representation shown along line X2-X2′ in FIG. 19, in accordance with some embodiments.

As shown in FIGS. 20A-1 and 20A-3, the bottom layer 134 is formed in the S/D recess 130, and the bottom isolation layer 135 is formed on the bottom layer 134. In some embodiments, the bottom layer 134 is made of SiGe. The back-side contact structure 178 is through the bottom layer 134 and the bottom isolation layer 135 to form the reversed T-shaped structure.

FIG. 20A-2, is similar to, or the same as FIG. 3O-2. FIG. 20A-4, is similar to, or the same as FIG. 3O-4.

It should be noted that, the mask layer 117 directly on the isolation structure 116, the dielectric layer 131 directly below the nanostructures 108′ and the bottom isolation layer 135 directly below the S/D structure 136 have different functions.

The mask layer 117 is formed on the isolation structure 116 to use as the etch stop layer and to protect the isolation structure 116. When performing the step of forming the gaps 143 (shown in FIGS. 3J-2 and 3J-3), the isolation structure 116 may be removed by the etching process, the mask layer 117 is used to prevent the isolation structure 116 from being etched or damaged. If the isolation structure 116 is removed by the etching process, the first gate structure 142a and the second gate structure 142b are formed deeper than expected. The performance of the semiconductor structure may be degraded by forming the deep first gate structure 142a and the second gate structure 142b. Therefore, the unwanted capacitance generated from the deep first gate structure 142a and the second gate structure 142b can be reduced. The performance of the semiconductor structure is improved by forming the mask layer 117 on the isolation structure.

The dielectric layer 131 is directly under the nanostructures 108′, the first gate structure 142a and the second gate structure 142b, and the first gate structure 142a and the second gate structure 142b are protected by the dielectric layer 131. Therefore, the dielectric layer 131 is used as an etch stop layer to prevent the nanostructures 108′, the first gate structure 142a and the second gate structure 142b from being damaged by the etching process for forming the trench for the back-side contact structure 178. In addition, the unwanted leakage between the back-side contact structure 178 and the first gate structure 142a and the second gate structure 142b are reduced. Therefore, the performance of the semiconductor structure is improved by forming the dielectric layer 131 directly below the first gate structure 142a and the second gate structure 142b.

Furthermore, the dielectric layer 131 is directly under the nanostructures 108′, rather than a Si base fin structure 105, the unwanted leakage or parasitic capacitance between the Si base fin structures 105 can be reduced. Therefore, the performance of the semiconductor structure is improved by forming the dielectric layer 131 directly below the nanostructures 108′.

It should be appreciated that the semiconductor structures 100a to 100g having different number of nanostructures 108′ (or channel layers) in different region for performing different functions described above may also be applied to FinFET structures, although not shown in the figures.

It should be noted that same elements in FIGS. 1A to 20A-4 may be designated by the same numerals and may include similar or the same materials and may be formed by similar or the same processes; therefore such redundant details are omitted in the interest of brevity. In addition, although FIGS. 1A to 20A-4 are described in relation to the method, it will be appreciated that the structures disclosed in FIGS. 1A to 20A-4 are not limited to the method but may stand alone as structures independent of the method. Similarly, although the methods shown in FIGS. 1A to 20A-4 are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. A number of nanostructures are formed over a substrate, and an isolation structure formed over the substrate. A dielectric layer is formed below the nanostructures to protect the nanostructures. A mask layer is formed on the isolation structure to protect the isolation structure. A gate structure formed on the nanostructures, and gate spacer layers formed on opposite sidewall surfaces of the gate structure. An S/D structure formed adjacent to the gate structure. A bottom isolation layer is formed below the S/D structure to reduce the leakage. A back-side contact structure is formed below the S/D structure. When a trench of the back-side contact structure is formed, the dielectric layer directly below the nanostructures and the mask layer directly below the gate structure are used as etch stop layer to protect the nanostructures and gate structure. Therefore, the risk of short problem can be reduced. In addition, the mask layer protect the isolation structure from being etched or damaged during the nanostructures formation process. Therefore, the unwanted capacitance can be reduced. The mask layer directly on the isolation structure, the dielectric layer directly below the nanostructures and the bottom isolation layer directly below the S/D structure have different functions to improve the performance of semiconductor structure.

In some embodiments, a semiconductor structure is provided. The semiconductor structure includes an isolation structure formed over a substrate, and a mask layer formed over the isolation structure. The semiconductor structure includes nanostructures formed over the substrate along a first direction, and a dielectric layer below the nanostructures along the first direction. The semiconductor structure also includes a gate structure formed over the nanostructures along a second direction. The semiconductor structure includes a gate spacer layer formed adjacent to the gate structure along the second direction, and the mask layer is directly below the gate spacer layer.

In some embodiments, a semiconductor structure is provided. The semiconductor structure includes an isolation structure formed over a substrate, and a mask layer formed over the isolation structure. The semiconductor structure includes nanostructures formed over the substrate along a first direction, and a gate structure formed over the nanostructures along a second direction. The semiconductor structure includes an S/D structure adjacent to the gate structure, and a bottom isolation layer formed below the S/D structure. The semiconductor structure includes a back-side contact structure formed below the S/D structure, and the back-side contact structure passes through the bottom isolation layer.

In some embodiments, a method for forming a semiconductor structure is provided. The method includes forming a fin structure over a substrate, and the fin structure includes first semiconductor material layers and second semiconductor material layers alternately stacked. The method includes forming an isolation structure over the substrate, and forming a mask layer over the isolation structure. The method includes forming a dummy gate structure over the fin structure, and forming a gate spacer layer adjacent to the dummy gate structure. The method includes removing a portion of the mask layer, and the mask layer is directly below the dummy gate structure and the gate spacer layer. The method includes removing the dummy gate structure, and removing the second semiconductor material layers to form nanostructures. The method includes forming a gate structure surrounding the nanostructures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
an isolation structure formed over a substrate;
a mask layer formed over the isolation structure;
nanostructures formed over the substrate along a first direction;
a dielectric layer below the nanostructures along the first direction;
a gate structure formed over the nanostructures along a second direction; and
a gate spacer layer formed adjacent to the gate structure along the second direction, wherein the mask layer is directly below the gate spacer layer.

2. The semiconductor structure as claimed in claim 1, wherein the mask layer is directly below the gate structure.

3. The semiconductor structure as claimed in claim 1, further comprising:
a fin spacer layer formed adjacent to the nanostructures along the first direction, wherein the mask layer is directly below the fin spacer layer.

4. The semiconductor structure as claimed in claim 1, further comprising:
a dielectric wall structure formed along the first direction, wherein a bottom surface of the dielectric wall structure is lower than a bottom surface of the mask layer.

5. The semiconductor structure as claimed in claim 1, further comprising:
an S/D structure adjacent to the gate structure; and
a bottom isolation layer formed below the S/D structure.

6. The semiconductor structure as claimed in claim 5, further comprising:
a back-side contact structure formed below the S/D structure, wherein the back-side contact structure is through the bottom isolation layer.

7. The semiconductor structure as claimed in claim 6, wherein the back-side contact structure is in direct contact with the mask layer.

8. The semiconductor structure as claimed in claim 1, further comprising:
a contact etch stop layer formed over the gate structure; and
a dielectric layer formed over the contact etch stop layer, wherein the mask layer is directly below the contact etch stop layer and the dielectric layer.

9. The semiconductor structure as claimed in claim 8, wherein a thickness of a first portion of the mask layer which is directly below the gate spacer layer is greater than a thickness of a second portion of the mask layer which is directly below the contact etch stop layer.

10. A semiconductor structure, comprising:
an isolation structure formed over a substrate;
a mask layer formed over the isolation structure;
nanostructures formed over the substrate along a first direction;
a gate structure formed over the nanostructures along a second direction;
an S/D structure adjacent to the gate structure;
a bottom isolation layer formed below the S/D structure; and
a back-side contact structure formed below the S/D structure, wherein the back-side contact structure passes through the bottom isolation layer.

11. The semiconductor structure as claimed in claim 10, wherein the back-side contact structure does not pass through the mask layer.

12. The semiconductor structure as claimed in claim 11, wherein the back-side contact structure is in direct contact with the mask layer.

13. The semiconductor structure as claimed in claim 10, further comprising:
a gate spacer layer formed adjacent to the gate structure along the second direction; and
a fin spacer layer formed adjacent to the nanostructures along the first direction, wherein the mask layer is directly below the fin spacer layer and the gate spacer layer.

14. The semiconductor structure as claimed in claim 10, wherein a top surface of the bottom isolation layer is higher than a top surface of the mask layer.

15. The semiconductor structure as claimed in claim 10, further comprising:
an inner spacer layer formed between the gate structure and the S/D structure, wherein the inner spacer layer is in direct contact with the bottom isolation layer.

16. The semiconductor structure as claimed in claim 10, further comprising:
a contact etch stop layer formed over the gate structure; and
a dielectric layer formed over the contact etch stop layer, wherein the mask layer is directly below the contact etch stop layer and the dielectric layer.

17. A method for forming a semiconductor structure, comprising:
forming a fin structure over a substrate, wherein the fin structure comprises first semiconductor material layers and second semiconductor material layers alternately stacked;
forming an isolation structure over the substrate;
forming a mask layer over the isolation structure;
forming a dummy gate structure over the fin structure;
forming a gate spacer layer adjacent to the dummy gate structure;
removing a portion of the mask layer, wherein the mask layer is directly below the dummy gate structure and the gate spacer layer;
removing the dummy gate structure;
removing the second semiconductor material layers to form nanostructures; and
forming a gate structure surrounding the nanostructures.

18. The method for forming the semiconductor structure as claimed in claim 17, further comprising:
removing a portion of fin structure to form an S/D trench;
forming a bottom isolation layer in the S/D trench; and
forming an S/D structure on the bottom isolation layer, wherein a top surface of the bottom isolation layer is higher than a top surface of the mask layer.

19. The method for forming the semiconductor structure as claimed in claim 17, further comprising:
forming a back-side contact structure below the S/D structure, wherein the back-side contact structure passes through the bottom isolation layer.

20. The method for forming the semiconductor structure as claimed in claim 17, further comprising:
forming a contact etch stop layer over the dummy gate structure and the mask layer; and
forming a dielectric layer over the contact etch stop layer, wherein the dielectric layer is formed on the mask layer.
